(19) United States
(12) Patent Application Publication
(10) Pub. No.: US 2024/0405016 A1
(43) Pub. Date: Dec. 5, 2024

(54) SEMICONDUCTOR MODULE

(71) Applicant: ROHM CO., LTD., Kyoto-shi (JP)

(72) Inventor: Shinya UMEKI, Kyoto-shi (JP)

(21) Appl. No.: 18/802,642

(22) Filed: Aug. 13, 2024

Related U.S. Application Data
(63) Continuation of application No. PCT/JP2023/006631, filed on Feb. 24, 2023.

(30) Foreign Application Priority Data
Mar. 31, 2022 (JP) 2022-061318

(51) Int. Cl. H01L 27/06; H01L 27/02; H01L 29/06; H01L 29/16; H01L 29/739

(52) U.S. Cl. CPC H01L 27/0623; H01L 27/0207; H01L 29/0611; H01L 29/1608; H01L 29/7397

(57) ABSTRACT

A semiconductor module includes an IGBT device, and a MISFET device that composes a parallel circuit together with the IGBT device. The semiconductor module generates a drain current of the MISFET device in a voltage range less than a built-in voltage of the IGBT device and generates a collector current of the IGBT device and a drain current of the MISFET device in a voltage range equal to or more than the built-in voltage.

### CROSS REFERENCE TO RELATED APPLICATIONS

The present application is a bypass continuation of International Patent Application No. PCT/JP2023/006631, filed on Feb. 24, 2023, which claims priority to Japanese Patent Application No. 2022-061318 filed in the Japan Patent Office on Mar. 31, 2022, and the entire disclosures of those applications are incorporated herein by reference.

### BACKGROUND

### 1. Field of the Disclosure

The present disclosure relates to a semiconductor module that includes an IGBT device and an MISFET device constituting a parallel circuit with the IGBT device.

### 2. Description of the Related Art

US20180138904A1 discloses a power transistor drive device that is provided with a parallel circuit including an insulated gate bipolar transistor and a field effect transistor. The field effect transistor is controlled to reach an ON state after the insulated gate bipolar transistor is controlled and reaches an ON state.

### BRIEF DESCRIPTION OF THE DRAWINGS

FIG. 1 is a circuit diagram showing an electric structure of a semiconductor module according to an embodiment.

FIG. 2 is a graph showing electrical properties of the semiconductor module shown in FIG. 1.

FIG. 3 is a plan view showing a configuration example of an IGBT device incorporated into the semiconductor module shown in FIG. 1.

FIG. 4 is a schematic cross-sectional view along line IV-IV shown in FIG. 3.

FIG. 5 is a plan view showing a layout example in a first chip shown in FIG. 3.

FIG. 6 is a cross-sectional view showing a main portion of a first active region shown in FIG. 5.

FIG. 7 is a plan view showing a configuration example of a MISFET device incorporated into the semiconductor module shown in FIG. 1.

FIG. 8 is a schematic cross-sectional view along line VIII-VIII shown in FIG. 7.

FIG. 9 is a plan view showing a layout example in a second chip shown in FIG. 7.

FIG. 10 is a cross-sectional view showing a main portion of a second active region shown in FIG. 7.

FIG. 11A is a graph showing a current-voltage characteristic according to a first adjustment example of the semiconductor module shown in FIG. 1.

FIG. 11B is a graph showing a current-voltage characteristic according to a second adjustment example of the semiconductor module shown in FIG. 1.

FIG. 11C is a graph showing a current-voltage characteristic according to a third adjustment example of the semiconductor module shown in FIG. 1.

FIG. 12 is a perspective view showing a configuration example of a semiconductor module.

FIG. 13 is a plan view showing an internal structure of the semiconductor module shown in FIG. 12.

FIG. 14 is a plan view showing another configuration example of the semiconductor module.

FIG. 15 is a plan view showing another configuration example of the semiconductor module.

FIG. 16 is a cross-sectional view showing another configuration example of the IGBT device.

FIG. 17 is a cross-sectional view showing another configuration example of the MISFET device.

FIG. 18 is a cross-sectional view showing another configuration example of the MISFET device.

FIG. 19 is a cross-sectional view showing another configuration example of the MISFET device.

FIG. 20 is a cross-sectional view showing another configuration example of the MISFET device.

### DETAILED DESCRIPTION OF THE PREFERRED EMBODIMENTS

Embodiments will be hereinafter described in detail with reference to the accompanying drawings. The accompanying drawings are schematic views, and are not strictly shown, and do not necessarily coincide with each other in reduced scale and the like. Also, the same reference sign is assigned to a constituent that corresponds to each constituent in the accompanying drawings, and a duplicated description of this constituent is omitted or simplified. A description of a constituent, which has not yet been omitted or simplified, is applied to a corresponding constituent a description of which has been omitted or simplified.

In a case in which the term “substantially equal” is used when components including a comparison target are described, this term includes a numerical value (form) equal to a numerical value (form) of the comparison target, and, in addition, includes a numerical error falling within the range of +10% based on the numerical value (form) of the comparison target. Although the terms “first,” “second,” and “third,” etc., are used in the embodiments, these are symbols assigned to the name of each constituent in order to clarify the explanatory order, and are not assigned to the effect that the name of each constituent is limited.

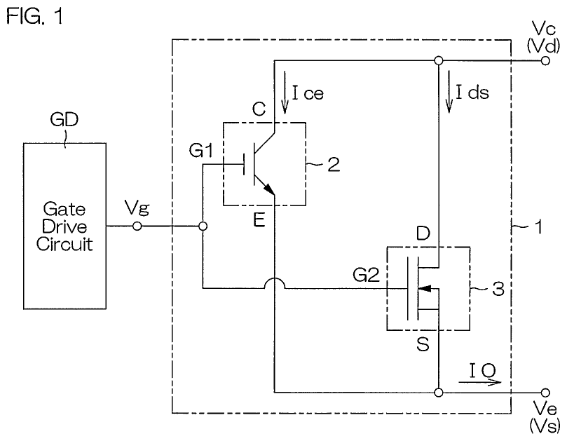

FIG. 1 is a circuit diagram showing an electric structure of a semiconductor module 1 according to an embodiment. Referring to FIG. 1, the semiconductor module 1 includes an IGBT device 2 (Insulated Gate Bipolar Transistor device) and a MISFET device 3 (Metal Semiconductor Field Effect Transistor device) that forms a parallel switching circuit together with the IGBT device 2.

The IGBT device 2 is a bipolar type first semiconductor switching device (first semiconductor device) having an IGBT, and includes a collector C, an emitter E, and a first gate G1. The MISFET device 3 is a unipolar type second semiconductor switching device (second semiconductor device) having a MISFET, and includes a drain D, a source S, and a second gate G2.

The drain D of the MISFET device 3 is electrically connected to the collector C of the IGBT device 2. The source S of the MISFET device 3 is electrically connected to the emitter E of the IGBT device 2. The second gate G2 of the MISFET device 3 is electrically connected to the first gate G1 of the IGBT device 2.

The first gate G1 of the IGBT device 2 and the second gate G2 of the MISFET device 3 are electrically connected to a gate drive circuit GD, and a gate signal emitted from the gate drive circuit GD is input into the first gate G1 and into the second gate G2. In other words, the MISFET device 3 is controlled simultaneously with the IGBT device 2. The IGBT device 2 generates a collector current Ice in response to the gate signal, and the MISFET device 3 generates a drain current Ids in response to the gate signal.

The gate drive circuit GD may be a gate driver IC. The semiconductor module 1 may include the gate drive circuit GD as a component although a form is shown in FIG. 1 in which the semiconductor module 1 is electrically connected to the gate drive circuit GD.

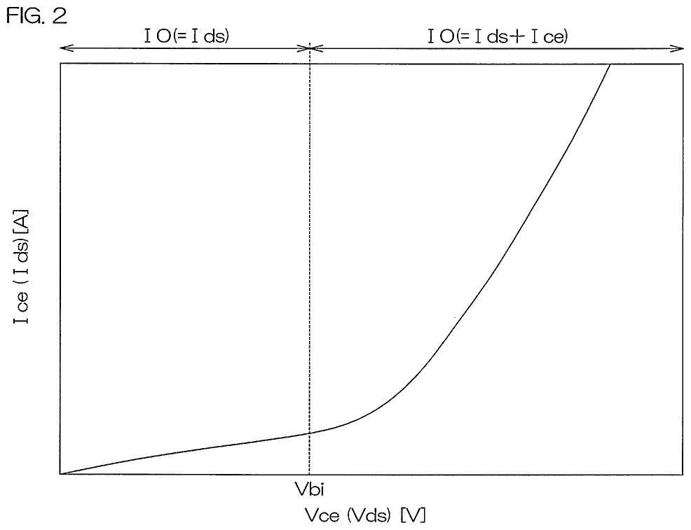

FIG. 2 is a graph showing electrical properties of the semiconductor module 1 shown in FIG. 1. An ordinate axis represents the collector current Ice (drain current Ids), and an abscissa axis represents a collector voltage Vce (drain voltage Vds) in FIG. 2. A characteristic of an output current IO of the semiconductor module 1 is shown in FIG. 2. The output current IO is an additional value of the collector current Ice and the drain current Ids.

Referring to FIG. 2, the semiconductor module 1 generates the output current IO consisting of only the drain current Ids of the MISFET device 3 within a voltage range less than a built-in voltage Vbi of the IGBT device 2. On the other hand, the semiconductor module 1 generates the output current IO including the drain current Ids of the MISFET device 3 and the collector current Ice of the IGBT device 2 within a voltage range equal to or more than the built-in voltage Vbi of the IGBT device 2.

The IGBT device 2 is the bipolar type semiconductor switching device, and hence has a comparatively large loss in a low current region less than the built-in voltage Vbi, and has a comparatively small loss in a high current region equal to or more than the built-in voltage Vbi. A loss reduction effect of the high current region in the IGBT device 2 results from a conductivity modulation effect.

On the other hand, the MISFET device 3 is the unipolar type semiconductor switching device that differs from the IGBT device 2, and hence does not have the built-in voltage Vbi, and does not exert a conductivity modulation effect. The MISFET device 3 has a comparatively small loss in a low current region, and has a comparatively large loss in a high current region. The loss in the high current region of the MISFET device 3 is improved by enlarging the MISFET device 3, and yet the problem of costs or of a change in the layout occurs.

With the semiconductor module 1, the drain current Ids of the MISFET device 3 is used in the low current region, and therefore the loss of the IGBT device 2 in the low current region is reduced. Also, the collector current Ice of the IGBT device 2 and the drain current Ids of the MISFET device 3 are used in the high current region, and therefore the loss of the MISFET device 3 in the high current region is reduced.

Therefore, the semiconductor module 1 makes it possible to reduce both the loss in the low current region and the loss in the high current region without enlarging the MISFET device 3. Therefore, it is possible to provide the semiconductor module 1 that is capable of improving electrical properties. A form example of the IGBT device 2 incorporated into the semiconductor module 1 and a form example of the MISFET device 3 incorporated into the semiconductor module 1 will be hereinafter described.

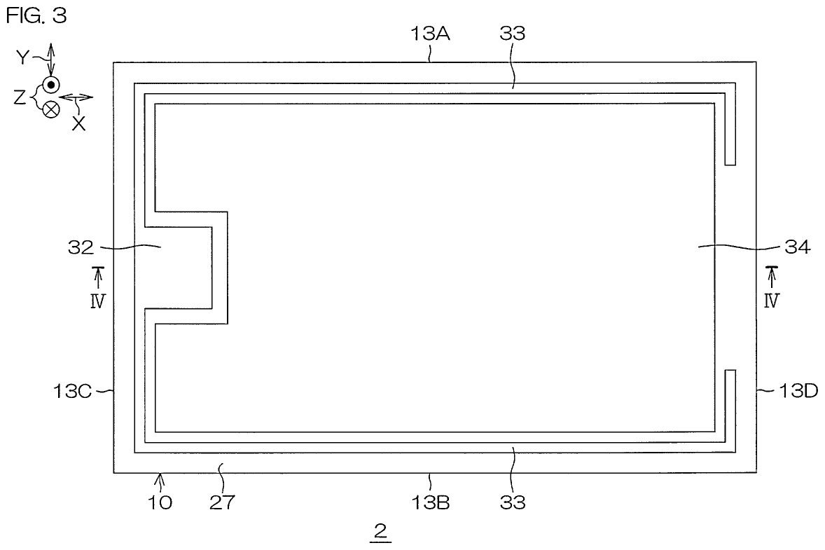

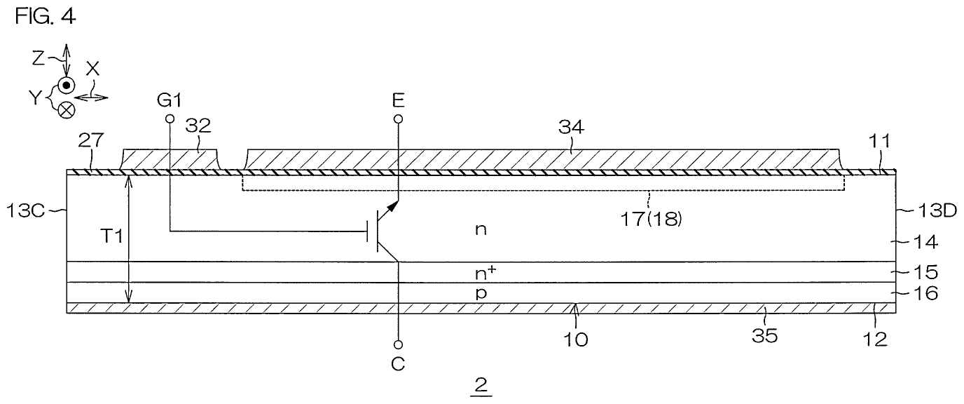

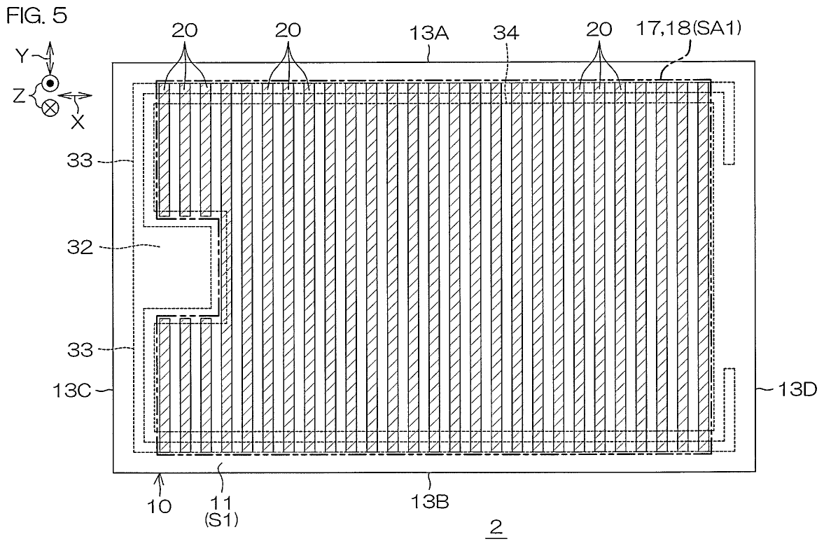

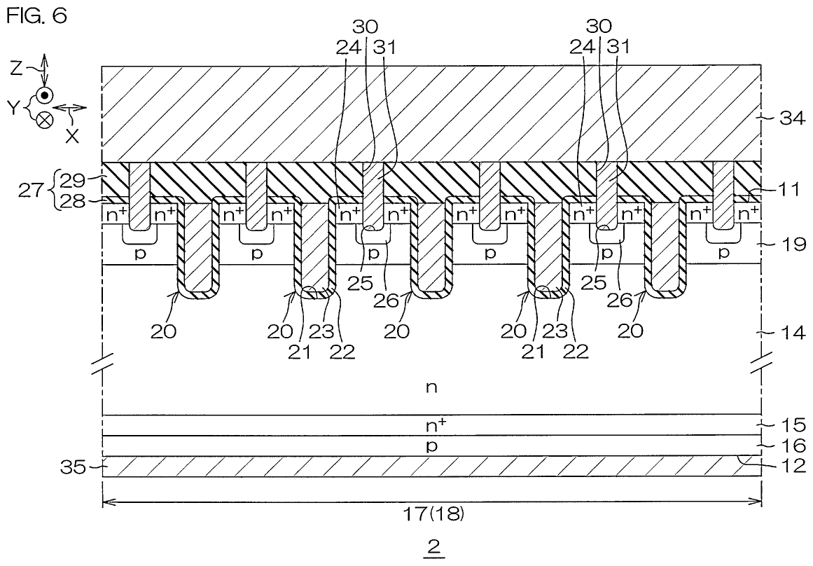

FIG. 3 is a plan view showing a configuration example of the IGBT device 2 incorporated into the semiconductor module 1 shown in FIG. 1. FIG. 4 is a schematic cross-sectional view along line IV-IV shown in FIG. 3. FIG. 5 is a plan view showing a layout example in a first chip 10 shown in FIG. 3. FIG. 6 is a cross-sectional view showing a main portion of a first active region 17 shown in FIG. 5.

The IGBT device 2 has a first breakdown voltage VB1. The first breakdown voltage VB1 is a reverse voltage in which a reverse voltage breakdown (avalanche breakdown) starts. For example, the first breakdown voltage VB1 may be not less than 500 V and not more than 1500 V. The first breakdown voltage VB1 may have a value that belongs to any one of the ranges of not less than 500 V and not more than 750 V, not less than 750 V and not more than 1000 V, not less than 1000 V and not more than 1250 V, and not less than 1250 V and not more than 1500 V. For example, the first breakdown voltage VB1 may be not less than 500 V and not more than 700 V or may be not less than 1100 V and not more than 1300 V.

Referring to FIG. 3 to FIG. 6, the IGBT device 2 includes the first chip 10 having a hexahedral shape (in detail, rectangular parallelepiped shape) in this embodiment. The first chip 10 is an Si chip made of Si (silicon) monocrystal. In other words, the IGBT device 2 is an “Si-IGBT device.” The first chip 10 has a single-layer structure consisting of an Si substrate.

The first chip 10 has a first chip thickness T1. The first chip thickness T1 may have a thickness of not less than 50 μm and not more than 200 μm. The first chip thickness T1 may have a value that belongs to any one of the ranges of not less than 50 μm and not more than 75 μm, not less than 75 μm and not more than 100 μm, not less than 100 μm and not more than 125 μm, not less than 125 μm and not more than 150 μm, not less than 150 μm and not more than 175 μm, and not less than 175 μm and not more than 200 μm.

For example, in a case in which the first breakdown voltage VB1 is not less than 500 V and not more than 700 V, the first chip thickness T1 may be not less than 60 μm and not more than 90 μm. For example, in a case in which the first breakdown voltage VB1 is not less than 1100 V and not more than 1300 V, the first chip thickness T1 may be not less than 120 μm and not more than 160 μm.

The first chip 10 has a first main surface 11 on one side, a second main surface 12 on the other side, and first to fourth side surfaces 13A to 13D that connect the first main surface 11 and the second main surface 12. The first and second main surfaces 11 and 12 are each formed in a quadrangular shape (in this embodiment, rectangular shape) in a plan view seen from their normal directions Z (hereinafter, referred to simply as a “plan view”). The normal direction Z is also a thickness direction of the first chip 10. Of course, the first and second main surfaces 11 and 12 may be each formed in a square shape in a plan view.

The first side surface 13A and the second side surface 13B extend in a first direction X along the first main surface 11, and face a second direction Y that intersects the first direction X (in detail, perpendicularly intersects). The first side surface 13A and the second side surface 13B form long sides of the first chip 10, respectively. The third side surface 13C and the fourth side surface 13D extend in the second direction Y, and face the first direction X. The third side surface 13C and the fourth side surface 13D form short sides of the first chip 10, respectively.

The first to fourth side surfaces 13A to 13D may each have a length of not less than 0.1 mm and not more than 20 mm in a plan view. The length of each of the first to fourth side surfaces 13A to 13D may have a value that belongs to any one of the ranges of not less than 0.1 mm and not more than 1 mm, not less than 1 mm and not more than 2.5 mm, not less than 2.5 mm and not more than 5 mm, not less than 5 mm and not more than 7.5 mm, not less than 7.5 mm and not more than 10 mm, not less than 10 mm and not more than 12.5 mm, not less than 12.5 mm and not more than 15 mm, not less than 15 mm and not more than 17.5 mm, and not less than 17.5 mm and not more than 20 mm.

The first chip 10 has a first chip area S1 in a plan view. The first chip area S1 is a multiplication value of the length of the first side surface 13A and the length of the third side surface 13C (i.e., a multiplication value of the length of the second side surface 13B and the length of the fourth side surface 13D).

The IGBT device 2 includes an n-type (first conductivity type) semiconductor region 14 formed inside the first chip 10. The semiconductor region 14 is formed in the whole area of the inside of the first chip 10. In this embodiment, the first chip 10 is consisting of an n-type Si chip, and the semiconductor region 14 is formed by use of the Si chip.

The IGBT device 2 includes an n-type buffer region 15 formed in a surficial portion of the second main surface 12. In this embodiment, the buffer region 15 is formed in a layer shape extending along the second main surface 12 in the whole area of the second main surface 12, and is exposed from the first to fourth side surfaces 13A to 13D. The buffer region 15 has an n-type impurity concentration higher than the semiconductor region 14. The presence or absence of the buffer region 15 is arbitrary, and a form in which the buffer region 15 does not exist may be employed.

The IGBT device 2 includes a p-type (second conductivity type) collector region 16 formed in the surficial portion of the second main surface 12. In this embodiment, the collector region 16 is formed in a surficial portion on the second main surface 12 side of the buffer region 15. The collector region 16 is formed in a layer shape extending along the second main surface 12 in the whole area of the second main surface 12, and is exposed from the second main surface 12 and from the first to fourth side surfaces 13A to 13D.

The IGBT device 2 includes the first active region 17 provided at the first main surface 11 of the first chip 10. The first active region 17 is a region that includes an IGBT structure 18 and that generates the collector current Ice. The first active region 17 has a first active area SA1 in a plan view.

For example, in a case in which a polygonal region including the IGBT structure 18 is set in a plan view (see an alternate long and two short dashed line of FIG. 3), the first active area SA1 is defined by the plane area of this polygonal region. In a case in which a plurality of first active regions 17 are provided, the first active area SA1 is defined by the total plane area of the plurality of first active regions 17.

The first active area SA1 takes various values in accordance with the first chip area S1. The first active area SA1 may be not less than 30% and less than 100% of the first chip area S1. The first active area SA1 may have a value that belongs to any one of the ranges of not less than 30% and not more than 40%, not less than 40% and not more than 50%, not less than 50% and not more than 60%, not less than 60% and not more than 70%, not less than 70% and not more than 80%, not less than 80% and not more than 90%, and not less than 90% and less than 100% of the first chip area S1.

The IGBT structure 18 includes a p-type base region 19 formed in a surficial portion of the first main surface 11 in the first active region 17. The base region 19 may be referred to as a “channel region.” The base region 19 is formed in a layer shape extending along the first main surface 11 in the whole area of the first active region 17.

The IGBT structure 18 includes a plurality of first trench structures 20 formed in the first main surface 11 in the first active region 17. A gate potential Vg is given to the plurality of first trench structures 20. The plurality of first trench structures 20 control the inversion and non-inversion of the channel. In other words, the IGBT structure 18 is consisting of a trench gate type one. The first trench structure 20 may be referred to as a “first trench gate structure.”

The plurality of first trench structures 20 are arrayed at a distance from each other in the first direction X, and are each formed in a belt shape extending in the Y. The plurality of first trench second direction structures 20 are formed in the first main surface 11 so as to pass through the base region 19 and so as to reach the semiconductor region 14.

The depth of each of the first trench structures 20 may be not less than 0.5 μm and not more than 10 μm. The depth of each of the first trench structures 20 may have a value that belongs to any one of the ranges of not less than 0.5 μm and not more than 2.5 μm, not less than 2.5 μm and not more than 5 μm, not less than 5 μm and not more than 7.5 μm, and not less than 7.5 μm and not more than 10 μm. Preferably, the depth of each of the first trench structures 20 is not less than 4 μm and not more than 8 μm.

Each of the first trench structures 20 includes a first trench 21, a first insulating film 22, and a first embedded electrode 23. The first trench 21 is formed in the first main surface 11, and defines a wall surface of the first trench structure 20. The first insulating film 22 covers a wall surface of the first trench 21 as a film. The first insulating film 22 may include a silicon oxide film. The first embedded electrode 23 is embedded in the first trench 21 with the first insulating film 22 between the first embedded electrode 23 and the first trench 21. In this embodiment, the first embedded electrode 23 includes conductive polysilicon.

The IGBT structure 18 includes a plurality of n-type emitter regions 24 formed in a region along the plurality of first trench structures 20 in a surficial portion of the base region 19. Each of the emitter regions 24 has an n-type impurity concentration higher than the semiconductor region 14. Each of the emitter regions 24 is formed in a region between two adjoining first trench structures 20 in the surficial portion of the base region 19. Each of the emitter regions 24 forms a channel of an IGBT in the base region 19 together with the semiconductor region 14.

The IGBT structure 18 includes a plurality of contact holes 25 formed in the first main surface 11 so as to expose the plurality of emitter regions 24. Each of the contact holes 25 is formed in a region between two adjoining first trench structures 20. Each of the contact holes 25 is formed at a distance from a bottom portion of the base region 19 toward the first main surface 11 side. Each of the contact holes 25 may pass through the emitter region 24, and may be formed at a distance from a bottom portion of the emitter region 24 from the first main surface 11 side. Each of the contact holes 25 is formed in a belt shape extending along the first trench structure 20 in a plan view.

The IGBT structure 18 includes a plurality of p-type first contact regions 26 formed in a region differing from the emitter region 24 in the surficial portion of the base region 19. Each of the first contact regions 26 has a p-type impurity concentration higher than the base region 19. Each of the first contact regions 26 is formed in a region along a wall surface of a corresponding one of the contact holes 25. Each of the first contact regions 26 is formed in a belt shape extending along the corresponding contact hole 25 in a plan view. A bottom portion of each of the first contact regions 26 is formed in a region between the bottom portion of the base region 19 and a bottom wall of the corresponding contact hole 25.

The IGBT device 2 includes a first interlayer insulating film 27 covering the first main surface 11. In this embodiment, the first interlayer insulating film 27 includes a first lower insulating film 28 and a first upper insulating film 29. The first lower insulating film 28 is connected to the first insulating film 22, and covers the first main surface 11 so as to expose the first embedded electrode 23. The first lower insulating film 28 may include a silicon oxide film. The first upper insulating film 29 covers the first lower insulating film 28 so as to cover the plurality of first trench structures 20. The first upper insulating film 29 may include a silicon oxide film. The first upper insulating film 29 is thicker than the first lower insulating film 28.

The first interlayer insulating film 27 includes a plurality of emitter openings 30 that expose the plurality of emitter regions 24. The plurality of emitter openings 30 are formed in a one-to-one correspondence with the plurality of contact holes 25 so as to communicate with the plurality of contact holes 25. The plurality of emitter openings 30 are formed in a belt shape extending along the plurality of contact holes 25.

The IGBT device 2 includes a plurality of contact electrodes 31 embedded in the first interlayer insulating film 27. The plurality of contact electrodes 31 are embedded in the plurality of emitter openings 30. The each of the contact electrodes 31 enters the inside of the contact hole 25 from the emitter opening 30, and is electrically connected to the emitter region 24 and to the first contact region 26 in the contact hole 25.

The IGBT device 2 includes a first gate electrode 32 arranged on the first interlayer insulating film 27. The gate potential Vg is given to the first gate electrode 32 from the outside. The first gate electrode 32 is arranged in a region along a central portion of the third side surface 13C in a plan view. The arrangement place of the first gate electrode 32 is arbitrary. For example, the first gate electrode 32 may be arranged in a region along a corner portion of the first chip 10 or at a central portion of the first chip 10 in a plan view.

The first gate electrode 32 faces a region located outside the first active region 17 across the first interlayer insulating film 27. Of course, the first gate electrode 32 may face the first active region 17 (i.e., first trench structures 20) across the first interlayer insulating film 27. The first gate electrode 32 is formed in a quadrangular shape in a plan view. The first gate electrode 32 may be formed in a circular shape or in a polygonal shape in a plan view.

The first gate electrode 32 includes a conductive material differing from that of the first embedded electrode 23. The first gate electrode 32 may include at least one among a Ti-based metal film, an A1-based metal film, and a Cu-based metal film. The Ti-based metal film may include at least one of a Ti film and a TiN film (in this description, the same applies hereinafter).

The Al-based metal film may include at least one of a pure Al film (whose purity is 99% or more) and an Al alloy film (in this description, the same applies hereinafter). The Cu-based metal film may include at least one of a pure Cu film (whose purity is 99% or more) and a Cu alloy film (in this description, the same applies hereinafter).

The Al alloy film and the Cu alloy film may include at least one among an AlCu alloy film, an AlSi alloy film, and an AlSiCu alloy film (in this description, the same applies hereinafter). In this embodiment, the gate electrode has a laminated structure including a Ti-based metal film and an Al-based metal film laminated in that order from the first interlayer insulating film 27 side. The first gate electrode 32 may be referred to as a “first gate metal.”

The IGBT device 2 includes a first gate wiring line 33 arranged on the first interlayer insulating film 27. The first gate wiring line 33 is electrically connected to the first gate electrode 32 and to the plurality of first trench structures 20, and transmits the gate potential Vg given to the first gate electrode 32 to the plurality of first trench structures 20.

In detail, the first gate wiring line 33 is led out from the first gate electrode 32 onto the first interlayer insulating film 27 in a plan view, and extends in a belt shape along the first to third side surfaces 13A to 13C so as to intersect (in detail, perpendicularly intersect) both end portions of the plurality of first trench structures 20. The first gate wiring line 33 is electrically connected to the plurality of first trench structures 20 through the first interlayer insulating film 27. The first gate wiring line 33 includes the same conductive material as the first gate electrode 32.

The IGBT device 2 includes an emitter electrode 34 arranged on the first interlayer insulating film 27. An emitter potential Ve is given to the emitter electrode 34 from the outside. The emitter electrode 34 is arranged in a region surrounded by both the first gate electrode 32 and the first gate wiring line 33 on the first interlayer insulating film 27 so as to cover the first active region 17.

The emitter electrode 34 faces the plurality of first trench structures 20 across the first interlayer insulating film 27, and is electrically connected to the plurality of emitter regions 24 and to the plurality of first contact regions 26 through the first interlayer insulating film 27. In detail, the emitter electrode 34 is electrically connected to the plurality of emitter regions 24 and to the plurality of first contact regions 26 through the plurality of contact electrodes 31 that pass through the first interlayer insulating film 27.

The emitter electrode 34 includes the same conductive material as the first gate electrode 32. The emitter electrode 34 may be referred to as an “emitter metal.” In this embodiment, the emitter electrode 34 includes a conductive material differing from that of the plurality of contact electrodes 31. Of course, the emitter electrode 34 may include the same conductive material as the plurality of contact electrodes 31. In this case, a part, which is placed in the plurality of emitter openings 30, of the emitter electrode 34 may be formed as the plurality of contact electrodes 31.

In this embodiment, the emitter electrode 34 has a planar shape substantially similar to the planar shape of the first active region 17. In a case in which the planar shape of the emitter electrode 34 is substantially similar to the planar shape of the first active region 17, the first active area SA1 mentioned above may be defined by the plane area of the emitter electrode 34.

The IGBT device 2 includes a collector electrode 35 covering the second main surface 12. A collector potential Vc is given to the collector electrode 35. The collector electrode 35 makes an ohmic contact with the collector region 16 exposed from the second main surface 12. The collector electrode 35 may cover the whole area of the second main surface 12 so as to be continuous with a peripheral edge (first to fourth side surfaces 13A to 13D) of the first chip 10.

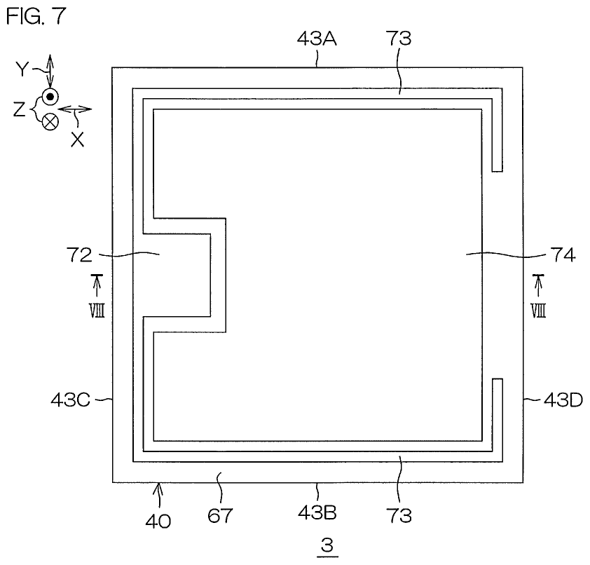

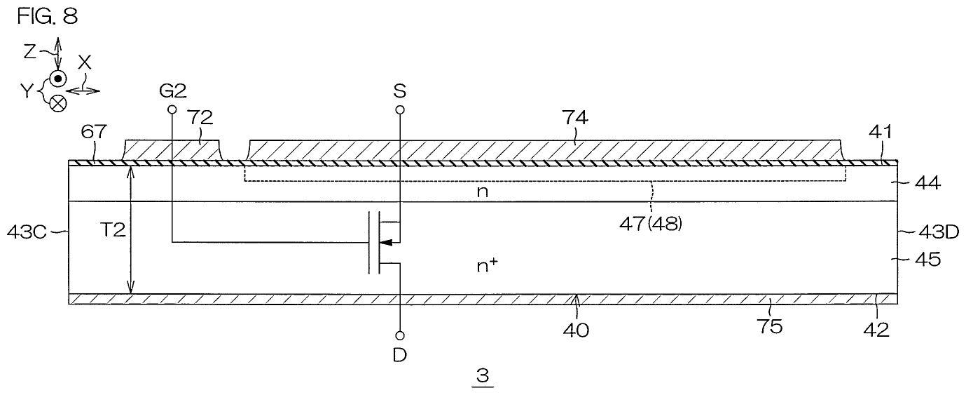

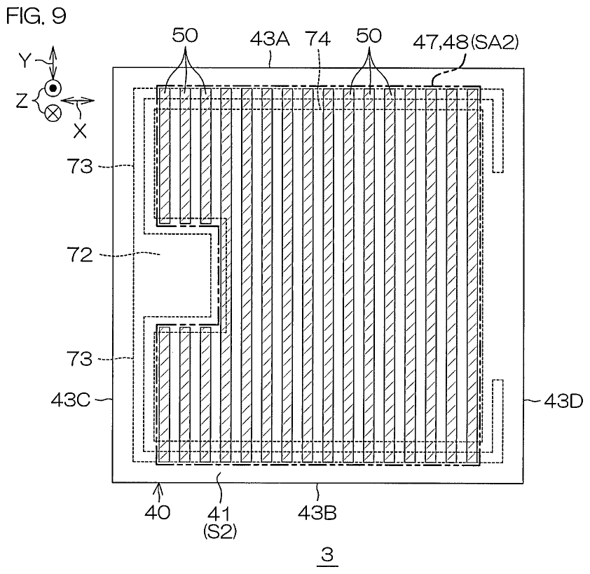

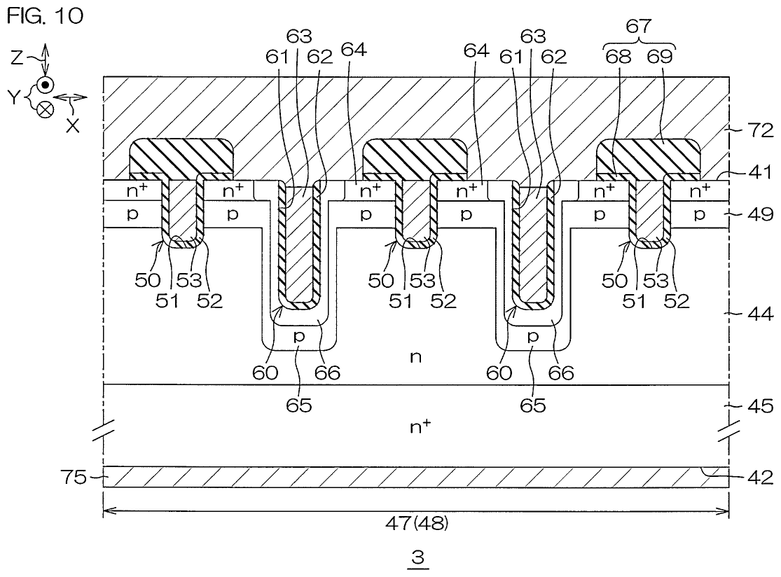

FIG. 7 is a plan view showing a configuration example of the MISFET device 3 incorporated into the semiconductor module 1 shown in FIG. 1. FIG. 8 is a schematic cross-sectional view along line VIII-VIII shown in FIG. 7. FIG. 9 is a plan view showing a layout example in a second chip 40 shown in FIG. 7. FIG. 10 is a cross-sectional view showing a main portion of a second active region 47 shown in FIG. 7.

The MISFET device 3 has a second breakdown voltage VB2. The second breakdown voltage VB2 is a reverse voltage in which a reverse voltage breakdown (avalanche breakdown) starts. Preferably, the second breakdown voltage VB2 is equal to or more than the first breakdown voltage VB1 of the IGBT device 2. Particularly preferably, the second breakdown voltage VB2 is more than the first breakdown voltage VB1. For example, the second breakdown voltage VB2 may be not less than 500 V and not more than 3000 V.

The second breakdown voltage VB2 may have a value that belongs to any one of the ranges of not less than 500 V and not more than 750 V, not less than 750 V and not more than 1000 V, not less than 1000 V and not more than 1250 V, not less than 1250 V and not more than 1500 V, not less than 1500 V and not more than 1750 V, not less than 1750 V and not more than 2000 V, not less than 2000 V and not more than 2250 V, not less than 2250 V and not more than 2500 V, not less than 2500 V and not more than 2750 V, and not less than 2750 V and not more than 3000 V. For example, the second breakdown voltage VB2 may be not less than 500 V and not more than 700 V, or may be not less than 1100 V and not more than 1300 V.

Referring to FIG. 7 to FIG. 10, the MISFET device 3 includes the second chip 40 having a hexahedral shape (in detail, rectangular parallelepiped shape). The second chip 40 is a chip consisting of a semiconductor monocrystal differing from that of the first chip 10. In detail, the second chip 40 is a wide bandgap semiconductor chip consisting of a wide bandgap semiconductor monocrystal.

In other words, the MISFET device 3 is a “wide bandgap semiconductor-MISFET device.” The wide bandgap semiconductor is a semiconductor having a bandgap exceeding the bandgap of Si. GaN (gallium nitride), SiC (silicon carbide), and C (diamond) are mentioned as examples of the wide bandgap semiconductor.

In this embodiment, the second chip 40 is consisting of a SiC chip including a hexagonal SiC monocrystal as an example of the wide bandgap semiconductor. In other words, the MISFET device 3 is a “SiC-MISFET device.” The hexagonal SiC monocrystal has a plurality of kinds of polytypes including 2H (Hexagonal)-SiC monocrystal, 4H-SiC monocrystal, 6H-SiC monocrystal, etc. The second chip 40 may include other polytypes although an example in which the second chip 40 includes the 4H-SiC monocrystal is shown in this embodiment.

The second chip 40 has a second chip thickness T2. The second chip thickness T2 may be equal to or more than the first chip thickness T1 of the IGBT device 2. The second chip thickness T2 may be less than the first chip thickness T1. The second chip thickness T2 may be substantially equal to the first chip thickness T1. The second chip thickness T2 may have a thickness of not less than 25 μm and not more than 200 μm.

The second chip thickness T2 may have a value that belongs to any one of the ranges of not less than 25 μm and not more than 50 μm, not less than 50 μm and not more than 75 μm, not less than 75 μm and not more than 100 μm, not less than 100 μm and not more than 125 μm, not less than 125 μm and not more than 150 μm, not less than 150 μm and not more than 175 μm, and not less than 175 μm and not more than 200 μm.

For example, in a case in which the value of the second breakdown voltage VB2 is not less than 500 V and not more than 700 V, the second chip thickness T2 may have a value that belongs to any one of the ranges of not less than 25 μm and not more than 50 μm, not less than 50 μm and not more than 75 μm, not less than 75 μm and not more than 100 μm, not less than 100 μm and not more than 125 μm, not less than 125 μm and not more than 150 μm, and not less than 150 μm and not more than 175 μm.

For example, in a case in which the value of the second breakdown voltage VB2 is not less than 1100 V and not more than 1300 V (not more than 3000 V), the second chip thickness T2 may have a value that belongs to any one of the ranges of not less than 50 μm and not more than 75 μm, not less than 75 μm and not more than 100 μm, not less than 100 μm and not more than 125 μm, not less than 125 μm and not more than 150 μm, not less than 150 μm and not more than 175 μm, and not less than 175 μm and not more than 200 μm.

For example, in a case in which the value of the second breakdown voltage VB2 is not less than 1100 V and not more than 1300 V (not more than 3000 V), the second chip thickness T2 may have a value that belongs to any one of the ranges of not less than 150 μm and not more than 160 μm, not less than 160 μm and not more than 170 μm, and not less than 170 μm and not more than 180 μm.

The second chip 40 has a first main surface 41 on one side, a second main surface 42 on the other side, and first to fourth side surfaces 43A to 43D that connect the first main surface 41 and the second main surface 42. The first and second main surfaces 41 and 42 are each formed in a quadrangular shape (in this embodiment, square shape) in a plan view seen from their normal directions Z (hereinafter, referred to simply as a “plan view”). The normal direction Z is also a thickness direction of the second chip 40. Of course, the first and second main surfaces 41 and 42 may be each formed in a rectangular shape in a plan view.

Preferably, the first and second main surfaces 41 and 42 are each formed by a c-plane of a SiC monocrystal. In this case, preferably, the first main surface 41 is formed by a silicon surface ((0001) plane) of the SiC monocrystal, and the second main surface 42 is formed by a carbon surface ((000-1) plane) of the SiC monocrystal.

The first and second main surfaces 41 and 42 may each have an off-angle so that the first and second main surfaces 41 and 42 are each inclined at a predetermined angle in a predetermined off-direction with respect to the c-plane. Preferably, the off-direction is an a-axial direction ([11-20] direction) of the SiC monocrystal. The off-angle may be more than 0° and not more than 10°. Preferably, the off-angle is 5° or less.

The first and second side surfaces 43A and 43B extend in the first direction X along the first main surface 41, and face the second direction Y that intersects (in detail, perpendicularly intersects) the first direction X. The third and fourth side surfaces 43C and 43D extend in the second direction Y, and face the first direction X. The first direction X may be an m-axial direction ([1-100] direction) of the SiC monocrystal, and the second direction Y may be the a-axial direction of the SiC monocrystal. Of course, the first direction X may be the a-axial direction of the SiC monocrystal, and the second direction Y may be the m-axial direction of the SiC monocrystal.

The first to fourth side surfaces 43A to 43D may each have a length of not less than 0.1 mm and not more than 20 mm in a plan view. The length of each of the first to fourth side surfaces 43A to 43D may have a value that belongs to any one of the ranges of not less than 0.1 mm and not more than 1 mm, not less than 1 mm and not more than 2.5 mm, not less than 2.5 mm and not more than 5 mm, not less than 5 mm and not more than 7.5 mm, not less than 7.5 mm and not more than 10 mm, not less than 10 mm and not more than 12.5 mm, not less than 12.5 mm and not more than 15 mm, not less than 15 mm and not more than 17.5 mm, and not less than 17.5 mm and not more than 20 mm.

The second chip 40 has a second chip area S2 in a plan view. The second chip area S2 is a multiplication value of the length of the first side surface 43A and the length of the third side surface 43C (i.e., multiplication value of the length of the second side surface 43B and the length of the fourth side surface 43D). Preferably, the second chip area S2 is less than the first chip area S1 of the IGBT device 2.

Particularly preferably, the second chip area S2 is not less than 0.1 times and not more than 0.6 times as large as the first chip area S1. In this case, the second chip area S2 may have a value that belongs to any one of the ranges of not less than 0.1 times and not more than 0.2 times, not less than 0.2 times and not more than 0.3 times, not less than 0.3 times and not more than 0.4 times, not less than 0.4 times and not more than 0.5 times, and not less than 0.5 times and not more than 0.6 times as large as the first chip area S1.

The MISFET device 3 includes an n-type first semiconductor region 44 formed in a region (surficial portion) on the first main surface 41 side in the second chip 40. The first semiconductor region 44 is formed in a layer shape extending along the first main surface 41, and is exposed from the first main surface 41 and from the first to fourth side surfaces 43A to 43D. In this embodiment, the first semiconductor region 44 is consisting of an epitaxial layer (SiC epitaxial layer) of a wide bandgap semiconductor.

The first semiconductor region 44 may have a thickness of not less than 1 μm and not more than 50 μm. The first semiconductor region 44 may have a value that belongs to any one of the ranges of not less than 1 μm and not more than 10 μm, not less than 10 μm and not more than 20 μm, not less than 20 μm and not more than 30 μm, not less than 30 μm and not more than 40 μm, and not less than 40 μm and not more than 50 μm. Preferably, the thickness of the first semiconductor region 44 is not less than 15 μm and not more than 25 μm.

The MISFET device 3 includes an n-type second semiconductor region 45 formed in a region (surficial portion) on the second main surface 42 side in the second chip 40. The second semiconductor region 45 is formed in a layer shape extending along the second main surface 42, and is exposed from the second main surface 42 and from the first to fourth side surfaces 43A to 43D. The second semiconductor region 45 has an n-type impurity concentration higher than the first semiconductor region 44, and is electrically connected to the first semiconductor region 44. In this embodiment, the second semiconductor region 45 is consisting of a monocrystal substrate (SiC monocrystal substrate) of a wide bandgap semiconductor.

In other words, the second chip 40 has a laminated structure including a substrate and an epitaxial layer. The second semiconductor region 45 may have a thickness of not less than 1 μm and not more than 200 μm. The second semiconductor region 45 may have a value that belongs to any one of the ranges of not less than 1 μm and not more than 25 μm, not less than 25 μm and not more than 50 μm, not less than 50 μm and not more than 75 μm, not less than 75 μm and not more than 100 μm, not less than 100 μm and not more than 125 μm, not less than 125 μm and not more than 150 μm, not less than 150 μm and not more than 175 μm, and not less than 175 μm and not more than 200 μm.

The thickness of the second semiconductor region 45 may be 5 μm or more. Preferably, the thickness of the second semiconductor region 45 is 10 μm or more. The thickness of the second semiconductor region 45 may be equal to or more than the thickness of the first semiconductor region 44. The thickness of the second semiconductor region 45 may be less than the thickness of the first semiconductor region 44. The thickness of the second semiconductor region 45 may be substantially equal to the thickness of the first semiconductor region 44. In this embodiment, the thickness of the second semiconductor region 45 is large than the thickness of the first semiconductor region 44.

The MISFET device 3 includes the second active region 47 provided at the first main surface 41 of the second chip 40. The second active region 47 is a region that includes a MISFET structure 48 and that generates the drain current Ids. The second active region 47 has a second active area SA2 in a plan view.

For example, in a case in which a polygonal region (see an alternate long and two short dashed line of FIG. 7) that includes the MISFET structure 48 is set in a plan view, the second active area SA2 is defined by the plane area of this polygonal region. In a case in which a plurality of second active regions 47 are provided, the second active area SA2 is defined by a total plane area of the plurality of second active regions 47.

The second active area SA2 takes various values in accordance with the second chip area S2. The second active area SA2 may be not less than 30% and less than 100% of the second chip area S2. The second active area SA2 may have a value that belongs to any one of the ranges of not less than 30% and not more than 40%, not less than 40% and not more than 50%, not less than 50% and not more than 60%, not less than 60% and not more than 70%, not less than 70% and not more than 80%, not less than 80% and not more than 90%, and not less than 90% and less than 100% of the second chip area S2.

Preferably, the second active area SA2 is less than the first active area SA1 of the IGBT device 2. Particularly preferably, the second active area SA2 is not less than 0.1 times and not more than 0.6 times as large as the first active area SA1. In this case, the second active area SA2 may have a value that belongs to any one of the ranges of not less than 0.1 times and not more than 0.2 times, not less than 0.2 times and not more than 0.3 times, not less than 0.3 times and not more than 0.4 times, not less than 0.4 times and not more than 0.5 times, and not less than 0.5 times and not more than 0.6 times as large as the first active area SA1.

The MISFET structure 48 includes a p-type body region 49 formed in the surficial portion of the first main surface 41 in the second active region 47. The body region 49 may be referred to as a “channel region.” The body region 49 is formed in a layer shape extending along the first main surface 41 in the whole area of the second active region 47.

The MISFET structure 48 includes a plurality of second trench structures 50 formed at the first main surface 41 in the second active region 47. The gate potential Vg of the IGBT device 2 is given to the plurality of second trench structures 50. The plurality of second trench structures 50 control the inversion and the non-inversion of a channel. In other words, the MISFET structure 48 is consisting of a trench gate type. The second trench structure 50 may be referred to as a “second trench gate structure.”

The plurality of second trench structures 50 are arrayed at a distance from each other in the first direction X, and are each formed in a belt shape extending in the second direction Y. The plurality of second trench structures 50 pass through the body region 49 so as to reach the first semiconductor region 44, and are formed at a distance from a bottom portion of the first semiconductor region 44 toward the first main surface 41 side.

Preferably, the plurality of second trench structures 50 are shallower than the plurality of first trench structures 20 of the IGBT device 2. The depth of each of the second trench structures 50 may be not less than 0.1 μm and not more than 3 μm. The depth of each of the second trench structures 50 may have a value that belongs to any one of the ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. Preferably, the depth of each of the first trench structures 20 is not less than 0.5 μm and not more than 1.5 μm.

Each of the second trench structures 50 includes a second trench 51, a second insulating film 52, and a second embedded electrode 53. The second trench 51 is formed in the first main surface 41, and defines a wall surface of the second trench structure 50. The second insulating film 52 covers a wall surface of the second trench 51 as a film. The second insulating film 52 may include a silicon oxide film. The second embedded electrode 53 is embedded in the second trench 51 with the second insulating film 52 between the second embedded electrode 53 and the second trench 51. In this embodiment, the second embedded electrode 53 includes conductive polysilicon.

The MISFET structure 48 includes a plurality of third trench structures 60 formed at the first main surface 41 in the second active region 47. The emitter potential Ve of the IGBT device 2 that serves as a source potential Vs is applied to the plurality of third trench structures 60. The third trench structure 60 may be referred to as a “trench source structure.”

The plurality of third trench structures 60 are each arranged in a region between adjoining two second trench structures 50. The plurality of third trench structures 60 are arrayed in the first direction X alternately with the plurality of second trench structures 50 in a plan view, and are each formed in a belt shape extending in the second direction Y. The plurality of third trench structures 60 pass through the body region 49 so as to reach the first semiconductor region 44, and are formed at a distance from the bottom portion of the first semiconductor region 44 toward the first main surface 41 side.

Each of the third trench structures 60 has a depth equal to or more than the depth of each of the second trench structures 50. In this embodiment, each of the third trench structures 60 is deeper than each of the second trench structures 50. Preferably, the depth of each of the third trench structures 60 is not less than 1.5 times and not more than 3 times as great as the depth of each of the second trench structures 50.

Preferably, each of the third trench structures 60 is shallower than each of the first trench structures 20 of the IGBT device 2. The depth of each of the third trench structures 60 may be not less than 0.5 μm and not more than 5 μm. The depth of each of the third trench structures 60 may have a value that belongs to any one of the ranges of not less than 0.5 μm and not more than 1 μm, not less than 1 μm and not more than 2 μm, not less than 2 μm and not more than 3 μm, not less than 3 μm and not more than 4 μm, and not less than 4 μm and not more than 5 μm. Preferably, the depth of each of the third trench structures 60 is not less than 1 μm and not more than 2.5 μm.

Each of the third trench structures 60 includes a third trench 61, a third insulating film 62, and a third embedded electrode 63. The third trench 61 is formed in the first main surface 41, and defines a wall surface of the third trench structure 60. The third insulating film 62 covers a wall surface of the third trench 61 as a film. The third insulating film 62 may include a silicon oxide film. The third embedded electrode 63 is embedded in the third trench 61 with the third insulating film 62 between the third embedded electrode 63 and the third trench 61. In this embodiment, the third embedded electrode 63 includes conductive polysilicon.

The MISFET structure 48 includes a plurality of n-type source regions 64 formed in a region along the plurality of second trench structures 50 in the surficial portion of the body region 49. Each of the source regions 64 has an n-type impurity concentration higher than the first semiconductor region 44. Each of the source regions 64 is formed in a region between the second trench structure 50 and the third trench structure 60 that adjoin each other in the surficial portion of the body region 49. Each of the source regions 64 forms a channel of a MISFET in the body region 49 together with the first semiconductor region 44.

The MISFET structure 48 includes a plurality of p-type well regions 65 formed in a region along the plurality of third trench structures 60 in the second chip 40. In this embodiment, the well region 65 has a p-type impurity concentration higher than the body region 49. Of course, the p-type impurity concentration of the well region 65 may be lower than the body region 49.

The plurality of well regions 65 cover a wall surface of the third trench structure 60 in the second chip 40, and are electrically connected to the body region 49 in the surficial portion of the first main surface 41. The plurality of well regions 65 are formed at a distance from the bottom portion of the first semiconductor region 44 toward the first main surface 41 side, and face the second semiconductor region 45 across a part of the first semiconductor region 44. The plurality of well regions 65 make a pn junction portion with the first semiconductor region 44.

The MISFET structure 48 includes a plurality of p-type second contact regions 66 formed in a region along the plurality of third trench structures 60 in the plurality of well regions 65. The second contact region 66 has a p-type impurity concentration higher than the body region 49. In this embodiment, the p-type impurity concentration of the second contact region 66 is higher than the well region 65.

The plurality of second contact regions 66 cover the wall surface of a corresponding one of the third trench structures 60 in a corresponding one of the well regions 65. The plurality of second contact regions 66 are led out from the inside of a corresponding one of the well regions 65 to the surficial portion of the body region 49 along the wall surface of a corresponding one of the third trench structures 60, and are exposed from the first main surface 41.

The MISFET device 3 includes a second interlayer insulating film 67 covering the first main surface 41. In this embodiment, the second interlayer insulating film 67 includes a second lower insulating film 68 and a second upper insulating film 69. The second lower insulating film 68 is connected to the second insulating film 52 and to the third insulating film 62, and covers the first main surface 41 so as to expose the second embedded electrode 53 and the third embedded electrode 63.

The second lower insulating film 68 may include a silicon oxide film. The second upper insulating film 69 covers the second lower insulating film 68 so as to cover the plurality of second trench structures 50 and the plurality of third trench structures 60. The second upper insulating film 69 may include a silicon oxide film. The second upper insulating film 69 is thicker than the second lower insulating film 68.

The MISFET device 3 includes a second gate electrode 72 arranged on the second interlayer insulating film 67. The gate potential Vg of the IGBT device 2 is given to the second gate electrode 72 from the outside. The second gate electrode 72 is arranged in a region along a central portion of the third side surface 43C in a plan view. The arrangement place of the second gate electrode 72 is arbitrary. For example, the second gate electrode 72 may be arranged in a region along a corner portion of the second chip 40 or at a central portion of the second chip 40 in a plan view.

The second gate electrode 72 faces a region located outside the second active region 47 across the second interlayer insulating film 67. Of course, the second gate electrode 72 may face the second active region 47 (i.e., plurality of second trench structures 50 and plurality of third trench structures 60) across the second interlayer insulating film 67. The second gate electrode 72 is formed in a quadrangular shape in a plan view. The second gate electrode 72 may be formed in a circular shape or in a polygonal shape in a plan view.

The second gate electrode 72 includes a conductive material differing from that of the second embedded electrode 53. The second gate electrode 72 may include at least one among a Ti-based metal film, an Al-based metal film, and a Cu-based metal film. In this embodiment, the second gate electrode 72 has a laminated structure including a Ti-based metal film and an Al-based metal film that are laminated in that order from the second interlayer insulating film 67 side. The second gate electrode 72 may be referred to as a “second gate metal.”

The MISFET device 3 includes a second gate wiring line 73 arranged on the second interlayer insulating film 67. The second gate wiring line 73 is electrically connected to the second gate electrode 72 and to the plurality of second trench structures 50, and transmits the gate potential Vg, which has been given to the second gate electrode 72, to the plurality of second trench structures 50.

In detail, the second gate wiring line 73 is led out from the second gate electrode 72 onto the second interlayer insulating film 67 in a plan view, and extends in a belt shape along the first to third side surfaces 43A to 43C so as to intersect (in detail, perpendicularly intersect) both end portions of the plurality of second trench structures 50. The second gate wiring line 73 is electrically connected to the plurality of second trench structures 50 through the second interlayer insulating film 67. The second gate wiring line 73 includes the same conductive material as the second gate electrode 72.

The MISFET device 3 includes a source electrode 74 arranged on the second interlayer insulating film 67. The emitter potential Ve of the IGBT device 2 that serves as the source potential Vs is given to the source electrode 74. The source electrode 74 is arranged in a region surrounded by the second gate electrode 72 and by the second gate wiring line 73 on the second interlayer insulating film 67 so as to cover the second active region 47. The source electrode 74 faces the plurality of second trench structures 50 across the second interlayer insulating film 67, and is electrically connected to the plurality of third trench structures 60, to the plurality of source regions 64, and to the plurality of second contact regions 66 through the second interlayer insulating film 67.

The source electrode 74 includes the same conductive material as the second gate electrode 72. The source electrode 74 may be referred to as a “source metal.” In this embodiment, the source electrode 74 has a planar shape that is substantially similar to the planar shape of the second active region 47. In a case in which the planar shape of the source electrode 74 is substantially similar to the planar shape of the second active region 47, the second active area SA2 mentioned above is defined by the plane area of the source electrode 74.

The MISFET device 3 includes a drain electrode 75 covering the second main surface 42. The collector potential Vc of the IGBT device 2 that serves as a drain potential Vd is given to the drain electrode 75. The drain electrode 75 makes an ohmic contact with the second semiconductor region 45 exposed from the second main surface 42. The drain electrode 75 may cover the whole area of the second main surface 42 so as to be continuous with a peripheral edge (first to fourth side surfaces 43A to 43D) of the second chip 40.

An adjustment example of the output current IO capable of appropriately restraining the loss in both a low current region and a high current region in the semiconductor module 1 will be hereinafter described in detail. The output current IO of the semiconductor module 1 is adjusted by adjusting a chip area ratio S2/S1 of the second chip area S2 of the MISFET device 3 to the first chip area S1 of the IGBT device 2. In other words, the output current IO is adjusted by adjusting an active area ratio SA2/SA1 of the second active area SA2 of the MISFET device 3 to the first active area SA1 of the IGBT device 2.

In a case in which the second chip area S2 (second active area SA2) of the MISFET device 3 is equal to or more than the first chip area S1 of the IGBT device 2 (first active area SA1), the current generation capability is improved in accordance with its value, and the loss of the MISFET device 3 in the high current region increases. For example, in a case in which the drain current Ids near a maximum rated value of the collector current Ice of the IGBT device 2 is generated in the MISFET device 3, the loss of the MISFET device 3 in the high current region becomes extremely high. In these cases, an advantage obtained by connecting the MISFET device 3 in parallel with the IGBT device 2 is small.

For example, the semiconductor module 1 can be incorporated into an inverter, a DC/DC converter, and a PFC (power factor correction) circuit as a use aspect. In the case of the inverter, the collector current Ice of 20% to 40% of the maximum rated value is generally used. In the case of the DC/DC converter or the PFC circuit, the collector current Ice of 30% to 50% of the maximum rated value is generally used.

The MISFET device 3 is provided on the assumption that the MISFET device 3 is used in the low current region, and therefore the drain current Ids falling within a current range even lower than the aforementioned current range is required to be efficiently generated. Therefore, an advantage obtained by enlarging the second chip area S2 (second active area SA2) of the MISFET device 3 is small.

Therefore, preferably, the second chip area S2 (second active area SA2) of the MISFET device 3 is set to be less than the first chip area S1 (first active area SA1) of the IGBT device 2 in order to limit the current generation capability of the MISFET device 3. Particularly preferably, the chip area ratio S2/S1 (active area ratio SA2/SA1) is not less than 0.1 and not more than 0.6.

Further, the MISFET device 3 is provided on the assumption that the MISFET device 3 is used in the low current region, and therefore the MISFET device 3 is required be small in size than the IGBT device 2, and, on the other hand, the MISFET device 3 is connected in parallel with the IGBT device 2 that is provided on the assumption that the IGBT device 2 is used in a high current operation, and therefore the MISFET device 3 is required to have a withstand voltage equal to or more than the withstand voltage of the IGBT device 2.

In this embodiment, the MISFET device 3 has the second breakdown voltage VB2 equal to or more than the first breakdown voltage VB1 of the IGBT device 2. The MISFET device 3 that fulfills the conditions of being small in size and being high in withstand voltage is achieved by employing the second chip 40 made of a wide bandgap semiconductor (in this embodiment, made of SiC).

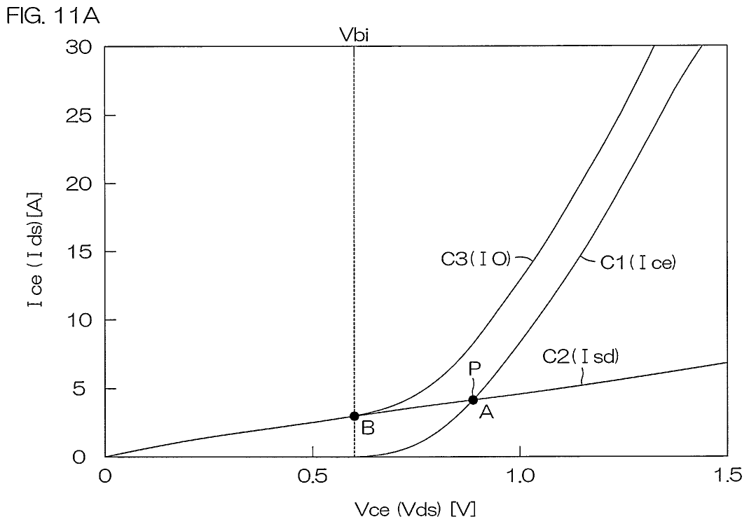

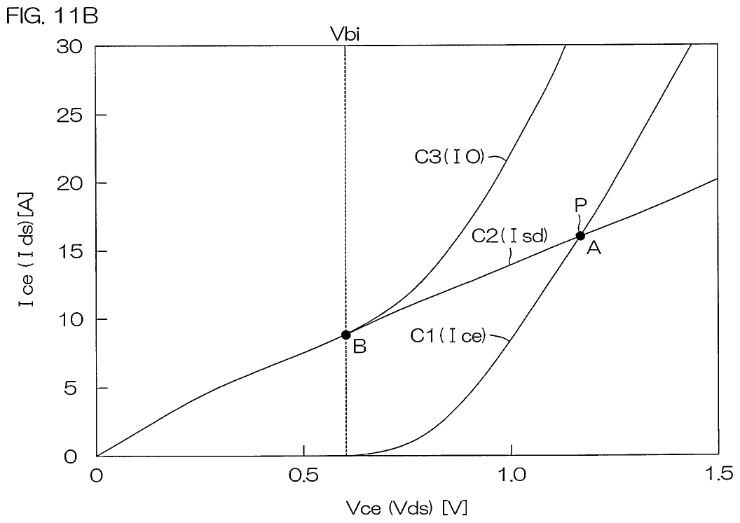

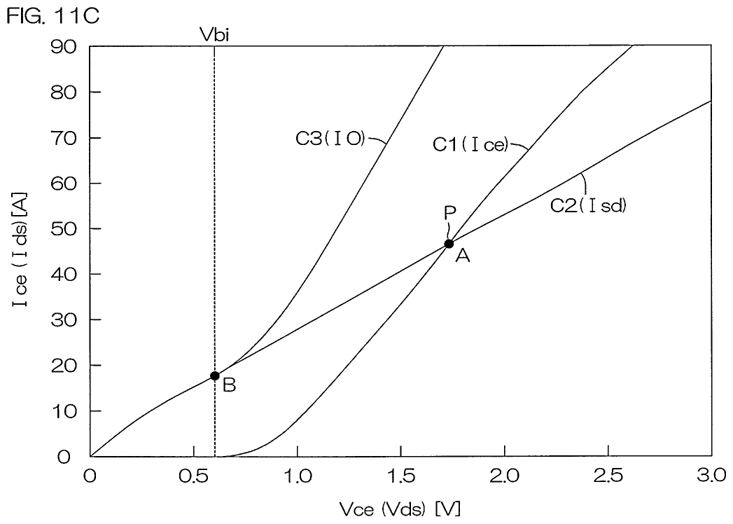

FIG. 11A is a graph showing a current-voltage characteristic according to a first adjustment example of the semiconductor module 1 shown in FIG. 1. FIG. 11B is a graph showing a current-voltage characteristic according to a second adjustment example of the semiconductor module 1 shown in FIG. 1. FIG. 11C is a graph showing a current-voltage characteristic according to a third adjustment example of the semiconductor module 1 shown in FIG. 1. In FIG. 11A to FIG. 11C, the ordinate axis represents the collector current Ice (drain current Ids), and the abscissa axis represents the collector voltage Vce (drain voltage Vds).

A first characteristic C1, a second characteristic C2, and a third characteristic C3 are each shown in FIG. 11A to FIG. 11C. The first characteristic C1 shows the individual collector current Ice when the IGBT device 2 is used as a single independent device. The second characteristic C2 shows the individual drain current Ids when the MISFET device 3 is used as a single independent device. The third characteristic C3 shows the output current IO when a parallel switching circuit including the IGBT device 2 and the MISFET device 3 is used. The output current IO is an additional value of the individual collector current Ice and the individual drain current Ids.

In FIG. 11A, first to third characteristics C1 to C3 are shown when the chip area ratio S2/S1 (active area ratio SA2/SA1) is adjusted to be 0.1. In FIG. 11B, first to third characteristics C1 to C3 are shown when the chip area ratio S2/S1 (active area ratio SA2/SA1) is adjusted to be 0.3. In FIG. 11C, first to third characteristics C1 to C3 are shown when the chip area ratio S2/S1 (active area ratio SA2/SA1) is adjusted to be 0.6.

Referring to FIG. 11A to FIG. 11C, the individual drain current Ids (individual collector current Ice) at an intersection P between the first characteristic C1 and the second characteristic C2 is set as a first current value A, and the individual drain current Ids when the built-in voltage Vbi is applied (in detail, when the drain voltage Vds equal to the built-in voltage Vbi is applied) is set as a second current value B (B<A).

In this case, preferably, a current ratio A/B of the first current value A to the second current value B is more than 1 and not more than 3 (1<A/B≤3). The current ratio A/B may have a value that belongs to any one of the ranges of more than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, and not less than 2.75 and not more than 3. Particularly preferably, the current ratio A/B is not less than 1.1 and not more than 2.6.

Preferably, a difference value (A−B) between the first current value A and the second current value B is not less than 0.5 A and not more than 30 A. The difference value (A−B) may have a value that belongs to any one of the ranges of not less than 0.5 A and not more than 1 A, not less than 1 A and not more than 5 A, not less than 5 A and not more than 10 A, not less than 10 A and not more than 15 A, not less than 15 A and not more than 20 A, not less than 20 A and not more than 25 A, and not less than 25 A and not more than 30 A.

Preferably, the inclination of a straight line that connects the first current value A and the second current value B is more than 1 and not more than 30. The inclination of the straight line that connects the first current value A and the second current value B may have a value that belongs to any one of the ranges of more than 1 and not more than 5, not less than 5 and not more than 10, not less than 10 and not more than 15, not less than 15 and not more than 20, not less than 20 and not more than 25, and not less than 25 and not more than 30.

In FIG. 11A, the first current value A is adjusted to be 4.2 A, and the second current value B is adjusted to be 3.3 A. The built-in voltage Vbi is 0.6 V, and the collector voltage Vce (drain voltage Vds) is 0.9 V at the intersection P. The current ratio A/B is 1.27. The difference value (A−B) between the first current value A and the second current value B is 0.9 A. The inclination of the straight line that connects the first current value A and the second current value B is 3.

In FIG. 11B, the first current value A is adjusted to be 16 A, and the second current value B is adjusted to be 10.7 A. The built-in voltage Vbi is 0.6 V, and the collector voltage Vce (drain voltage Vds) is 1.16 V at the intersection P. The current ratio A/B is 1.5. The difference value (A−B) between the first current value A and the second current value B is 5.3 A. The inclination of the straight line that connects the first current value A and the second current value B is 9.46.

In FIG. 11C, the first current value A is adjusted to be 46 A, and the second current value B is adjusted to be 22.8 A. The built-in voltage Vbi is 0.6 V, and the collector voltage Vce (drain voltage Vds) is 1.7 V at the intersection P. The current ratio A/B is 2.02. The difference value (A−B) between the first current value A and the second current value B is 23.2 A. The inclination of the straight line that connects the first current value A and the second current value B is 21.1.

The semiconductor module 1 includes the IGBT device 2 and the MISFET device 3 as described above. The MISFET device 3 composes a parallel circuit together with the IGBT device 2. In the thus formed structure, the semiconductor module 1 generates the drain current Ids of the MISFET device 3 in a voltage range less than the built-in voltage Vbi of the IGBT device 2 and generates the collector current Ice of the IGBT device 2 and the drain current Ids of the MISFET device 3 in a voltage range equal to or more than the built-in voltage Vbi.

With this structure, the drain current Ids of the MISFET device 3 is used in the low current region, and therefore the loss of the IGBT device 2 in the low current region is reduced. Also, the collector current Ice of the IGBT device 2 and the drain current Ids of the MISFET device 3 are used in the high current region, and therefore the loss of the MISFET device 3 in the high current region is reduced. Therefore, it is possible to provide the semiconductor module 1 capable of improving electrical properties.

Preferably, the IGBT device 2 has the first breakdown voltage VB1, and the MISFET device 3 has the second breakdown voltage VB2 equal to or more than the first breakdown voltage VB1. This structure makes it possible to appropriately use the MISFET device 3, which is provided on the assumption that the MISFET device 3 is used in the environment of a low voltage and a low current, together with the IGBT device 2, which is provided on the assumption that the IGBT device 2 is used in the environment of a high voltage and a high current. The first breakdown voltage VB1 may be not less than 500 V and not more than 1500 V. The second breakdown voltage VB2 may be not less than 500 V and not more than 3000 V.

Preferably, the IGBT device 2 includes the first chip 10 made of Si. This structure makes it possible to use the IGBT device 2 that is comparatively low in cost. Preferably, the MISFET device 3 includes the second chip 40 made of a wide bandgap semiconductor. The wide bandgap semiconductor makes it possible to make the second chip 40 having a high withstand voltage and a downsized structure simultaneously and easily. Therefore, it is possible to easily achieve the high withstand voltage MISFET device 3 that complies with the usage environment of the IGBT device 2. Particularly preferably, the wide bandgap semiconductor is SiC.

Preferably, the first chip 10 has the first chip area S1, and the second chip 40 has the second chip area S2 smaller than the first chip area S1. This structure makes it possible to limit the current generation capability of the MISFET device 3. This makes it possible to appropriately reduce the loss of the MISFET device 3 in the low current region. Particularly preferably, the second chip area S2 is not less than 0.1 times and not more than 0.6 times as large as the first chip area S1. The second chip 40 may be thinner than the first chip 10. The second chip 40 may be thicker than the first chip 10.

With respect to the first characteristic C1 showing the individual collector current Ice of the IGBT device 2 serving as a single independent device and with respect to the second characteristic C2 showing the individual drain current Ids of the MISFET device 3 serving as a single independent device, preferably, the current ratio A/B of the first current value A to the second current value B is more than 1 and not more than 3 (1<A/B≤3) when the individual drain current Ids (individual collector current Ice) at the intersection P between the first characteristic C1 and the second characteristic C2 is set as a first current value A and when the individual drain current Ids during the application of the built-in voltage Vbi is set at the second current value B (B<A). This structure makes it possible to appropriately reduce both the loss in the low current region and the loss in the high current region.

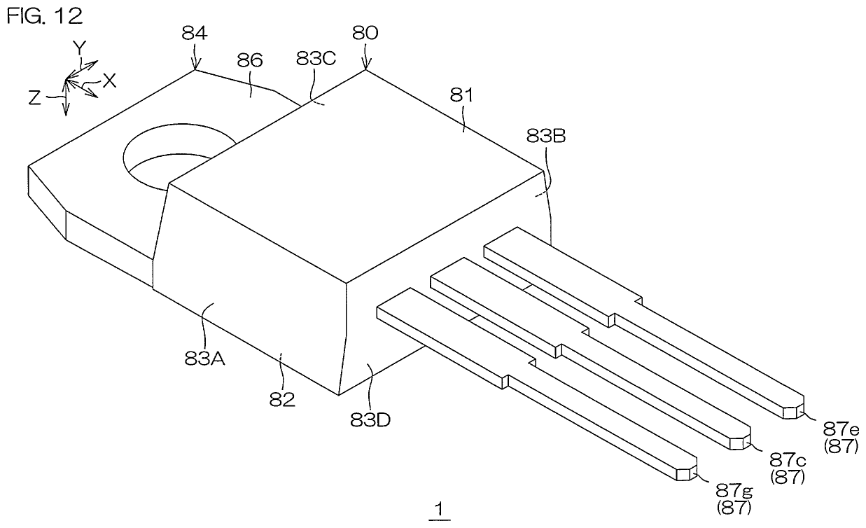

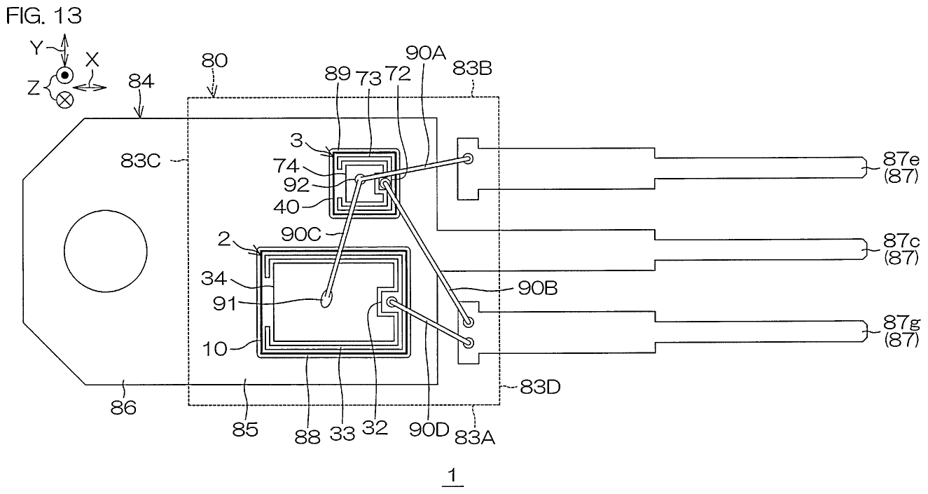

The form of the semiconductor module 1 is arbitrary, and is not limited to a specific form as long as a parallel switching circuit consisting of both the IGBT device 2 and the MISFET device 3 can be configured. A form example of the semiconductor module 1 is hereinafter shown. FIG. 12 is a perspective view showing a configuration example of the semiconductor module 1. FIG. 13 is a plan view showing an internal structure of the semiconductor module 1 shown in FIG. 12.

Referring to FIG. 12 and FIG. 13, the semiconductor module 1 has a package form of TO-220 in this embodiment. The semiconductor module 1 includes a package body 80 that is made of resin and formed in a hexahedral shape (in detail, rectangular parallelepiped shape). The package main body 80 may be consisting of thermosetting resin (for example, epoxy resin). The package main body 80 has a first surface 81 on one side, a second surface 82 on the other side, and first to fourth sidewalls 83A to 83D connecting the first and second surfaces 81 and 82.

The first and second surfaces 81 and 82 are each formed in a quadrangular shape in a plan view seen from their normal directions Z. The first sidewall 83A and the second sidewall 83B extend in the first direction X, and face the second direction Y perpendicular to the first direction X. The third sidewall 83C and the fourth sidewall 83D extend in the second direction Y, and face the first direction X.

The semiconductor module 1 includes a support electrode 84 that is made of metal and arranged in the package body 80. The support electrode 84 may be exposed from the second surface 82. The support electrode 84 includes a support portion 85 and a lead-out portion 86. The support portion 85 is arranged in the package main body 80. The lead-out portion 86 is led out from the support portion 85 toward the third sidewall 83C side, and passes through the third sidewall 83C, and is placed outside the package main body 80. The lead-out portion 86 has a circular through hole.

The semiconductor module 1 includes a plurality of (in this embodiment, three) wiring electrodes 87 that is made of metal and led out outwardly from the inside of the package main body 80. The plurality of wiring electrodes 87 are arranged on the fourth sidewall 83D side with respect to the support electrode 84. The plurality of wiring electrodes 87 are each formed in a belt shape extending in an orthogonal direction (i.e., in the first direction X) of the fourth sidewall 83D. The wiring electrodes 87 on both sides are arranged at a distance from the support electrode 84, and the central wiring electrode 87 is formed integrally with the support electrode 84. The arrangement place of the wiring electrode 87 connected to the support electrode 84 is arbitrary.

The plurality of wiring electrodes 87 include an emitter wiring electrode 87e, a gate wiring electrode 87g, and a collector wiring electrode 87c. The emitter wiring electrode 87e may be referred to as a “source terminal” or as an “emitter source terminal.” The collector wiring electrode 87c may be referred to as a “drain terminal” or as a “collector drain terminal.” In this embodiment, the emitter wiring electrode 87e is arranged on the second sidewall 83B side, and the gate wiring electrode 87g is arranged on the first sidewall 83A side, and the collector wiring electrode 87c is arranged between the emitter wiring electrode 87e and the gate wiring electrode 87g.

The semiconductor module 1 includes the aforementioned IGBT device 2 arranged on the support electrode 84 (support portion 85) in the package main body 80. In this embodiment, the IGBT device 2 is arranged in a region on the first sidewall 83A side with respect to a central portion of the support electrode 84. In other words, the IGBT device 2 is arranged at a position close to the gate wiring electrode 87g.

The IGBT device 2 is arranged on the support electrode 84 in a posture in which the collector electrode 35 is directed to the support electrode 84. Also, the IGBT device 2 is arranged on the support electrode 84 in a posture in which the first gate electrode 32 is directed to the fourth sidewall 83D side in a plan view. The collector electrode 35 is electrically connected to the support electrode 84.

The IGBT device 2 is arranged at a first distance from the gate wiring electrode 87g, and is arranged at a second distance, which is larger than the first distance, from the emitter wiring electrode 87e. In this embodiment, the IGBT device 2 faces the gate wiring electrode 87g in the first direction X, and does not face the emitter wiring electrode 87e in the first direction X. The IGBT device 2 may face the collector wiring electrode 87c in the first direction X.

The semiconductor module 1 includes the aforementioned MISFET device 3 arranged on the support electrode 84 (support portion 85) at a distance from the IGBT device 2 in the package main body 80. In this embodiment, the MISFET device 3 is arranged on the second sidewall 83B side with respect to the IGBT device 2, and faces the IGBT device 2 in the second direction Y. In other words, the MISFET device 3 is arranged at a position closer to the emitter wiring electrode 87e than the IGBT device 2.

The MISFET device 3 is arranged on the support electrode 84 in a posture in which the drain electrode 75 is directed to the support electrode 84. Also, the MISFET device 3 is arranged on the support electrode 84 in a posture in which the second gate electrode 72 is directed to the fourth sidewall 83D side in a plan view. The drain electrode 75 is electrically connected to the collector electrode 35 of the IGBT device 2 through the support electrode 84, and is electrically connected to the collector wiring electrode 87c through the support electrode 84.

The MISFET device 3 is arranged at a third distance from the gate wiring electrode 87g, and is arranged at a fourth distance, which is smaller than the third distance, from the emitter wiring electrode 87e. In this embodiment, the MISFET device 3 faces the emitter wiring electrode 87e in the first direction X, and does not face the gate wiring electrode 87g in the first direction X. The MISFET device 3 may face the collector wiring electrode 87c in the first direction X.

The semiconductor module 1 includes a first conductive adhesive 88 interposed between the support electrode 84 (support portion 85) and the collector electrode 35. The first conductive adhesive 88 may include a solder or a metal paste. The solder may be a lead-free solder. The metal paste may include at least one among Au, Ag, and Cu. The Ag paste may be consisting of an Ag sintered paste. The Ag sintered paste is consisting of a paste in which nano-sized or micro-sized Ag particles have been added to an organic solvent.

The semiconductor module 1 includes a second conductive adhesive 89 interposed between the support electrode 84 (support portion 85) and the drain electrode 75. The second conductive adhesive 89 may include a solder or a metal paste. The solder may be a lead-free solder. The metal paste may include at least one among Au, Ag, and Cu. The Ag paste may be consisting of an Ag sintered paste.

The semiconductor module 1 includes a plurality of first to fourth conductive connection members 90A to 90D arranged in the package main body 80. In this embodiment, the plurality of first to fourth conductive connection members 90A to 90D are each consisting of a metal wire (i.e., bonding wire). The plurality of first to fourth conductive connection members 90A to 90D may include at least one among a gold wire, a copper wire, and an aluminum wire. Of course, at least one or all of the plurality of first to fourth conductive connection members 90A to 90D may be consisting of a metal plate, such as a metal clip, instead of the metal wire.

The first conductive connection member 90A is electrically and mechanically connected to the source electrode 74 of the MISFET device 3 and to the emitter wiring electrode 87e. The second conductive connection member 90B is electrically and mechanically connected to the second gate electrode 72 of the MISFET device 3 and to the gate wiring electrode 87g.

The third conductive connection member 90C is electrically connected to the emitter electrode 34 of the IGBT device 2 and to the emitter wiring electrode 87e. In detail, the third conductive connection member 90C includes a first connection portion 91 electrically and mechanically connected to the emitter electrode 34 of the IGBT device 2 and a second connection portion 92 electrically and mechanically connected to the source electrode 74 of the MISFET device 3, and is electrically connected to the emitter wiring electrode 87e through the first conductive connection member 90A.

In more detail, the second connection portion 92 of the third conductive connection member 90C is joined to the first conductive connection member 90A on the source electrode 74. In other words, the third conductive connection member 90C is electrically connected to the emitter wiring electrode 87e through the first conductive connection member 90A according to a stitch wire method.

Of course, the third conductive connection member 90C may be electrically and mechanically connected directly to the emitter electrode 34 and directly to the emitter wiring electrode 87e. The fourth conductive connection member 90D is electrically and mechanically connected to the first gate electrode 32 of the IGBT device 2 and to the gate wiring electrode 87g.

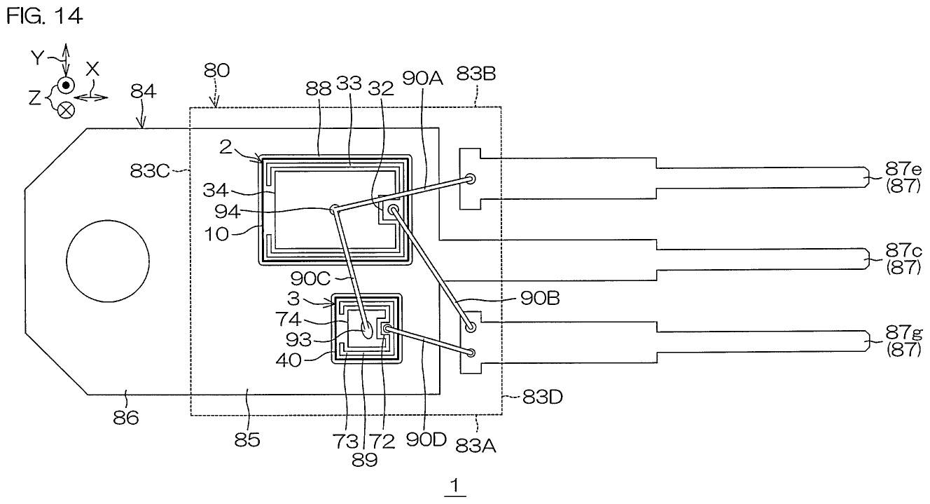

FIG. 14 is a plan view showing another configuration example of the semiconductor module 1. FIG. 14 has a form in which the arrangement place of the IGBT device 2 and the arrangement place of the MISFET device 3 have been replaced with each other in the semiconductor module 1 according to the first mode example. In other words, in this embodiment, the IGBT device 2 is arranged in a region on the second sidewall 83B side with respect to the central portion of the support electrode 84. Also, the IGBT device 2 is arranged at position close to the emitter wiring electrode 87e.

The IGBT device 2 is arranged at a first distance from the emitter wiring electrode 87e, and is arranged at a second distance, which is larger than the first distance, from the gate wiring electrode 87g. In this embodiment, the IGBT device 2 faces the emitter wiring electrode 87e in the first direction X, and does not face the gate wiring electrode 87g in the first direction X. The IGBT device 2 may face the collector wiring electrode 87c in the first direction X.

In this embodiment, the MISFET device 3 is arranged on the first sidewall 83A side with respect to the IGBT device 2, and faces the IGBT device 2 in the second direction Y. In other words, the MISFET device 3 is arranged at a position closer to the gate wiring electrode 87g than the IGBT device 2.

The MISFET device 3 is arranged at a third distance from the emitter wiring electrode 87e, and is arranged at a fourth distance, which is smaller than the third distance, from the gate wiring electrode 87g. In this embodiment, the MISFET device 3 faces the gate wiring electrode 87g in the first direction X, and does not face the emitter wiring electrode 87e in the first direction X. The MISFET device 3 may face the collector wiring electrode 87c in the first direction X.

The first conductive connection member 90A is electrically and mechanically connected to the emitter electrode 34 of the IGBT device 2 and to the emitter wiring electrode 87e. The second conductive connection member 90B is electrically and mechanically connected to the first gate electrode 32 of the IGBT device 2 and to the gate wiring electrode 87g.

The third conductive connection member 90C is electrically connected to the source electrode 74 of the MISFET device 3 and to the emitter wiring electrode 87e. In detail, the third conductive connection member 90C includes a first connection portion 93 electrically and mechanically connected to the source electrode 74 of the MISFET device 3 and a second connection portion 94 electrically and mechanically connected to the emitter electrode 34 of the IGBT device 2, and is electrically connected to the emitter wiring electrode 87e through the first conductive connection member 90A.

In more detail, the second connection portion 94 of the third conductive connection member 90C is joined to the first conductive connection member 90A on the emitter electrode 34. In other words, the third conductive connection member 90C is electrically connected to the emitter wiring electrode 87e through the first conductive connection member 90A according to a stitch wire method.

Of course, the third conductive connection member 90C may be electrically and mechanically connected directly to the source electrode 74 and directly to the emitter wiring electrode 87e. The fourth conductive connection member 90D is electrically and mechanically connected to the second gate electrode 72 of the MISFET device 3 and to the gate wiring electrode 87g.

In the semiconductor module 1 according to FIG. 14, there is a case in which the bending angle in the extending direction of the third conductive connection member 90C with respect to the extending direction of the first conductive connection member 90A becomes smaller (becomes steeper) depending on the arrangement place of the IGBT device 2 and the arrangement place of the MISFET device 3 than in the semiconductor module 1 according to FIG. 13. Therefore, preferably, the arrangement place of the IGBT device 2 and the arrangement place of the MISFET device 3 are those of the semiconductor module 1 according to FIG. 13 in consideration of the bending angle of the second conductive connection member 90B with respect to the first conductive connection member 90A.

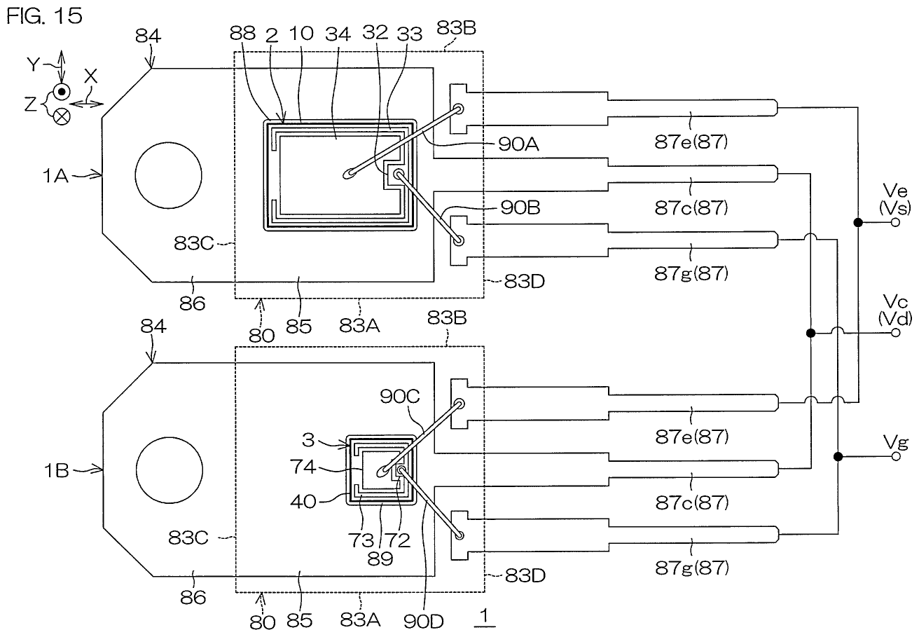

FIG. 15 is a plan view showing a still another configuration example of the semiconductor module 1. The semiconductor module 1 includes a first semiconductor module 1A and a second semiconductor module 1B. The first semiconductor module 1A includes the package main body 80, the support electrode 84, the plurality of wiring electrodes 87, the IGBT device 2, the first conductive adhesive 88, the first conductive connection member 90A, and the second conductive connection member 90B. The first conductive connection member 90A is electrically and mechanically connected to the emitter electrode 34 and to the emitter wiring electrode 87e. The second conductive connection member 90B is electrically and mechanically connected to the first gate electrode 32 and to the gate wiring electrode 87g.

The second semiconductor module 1B includes the package main body 80, the support electrode 84, the plurality of wiring electrodes 87, the MISFET device 3, the second conductive adhesive 89, the third conductive connection member 90C, and the fourth conductive connection member 90D. The third conductive connection member 90C is electrically and mechanically connected to the source electrode 74 and to the emitter wiring electrode 87e. The fourth conductive connection member 90D is electrically and mechanically connected to the second gate electrode 72 and to the gate wiring electrode 87g.

The emitter wiring electrode 87e of the second semiconductor module 1B is electrically connected to the emitter wiring electrode 87e of the first semiconductor module 1A. The gate wiring electrode 87g of the second semiconductor module 1B is electrically connected to the gate wiring electrode 87g of the first semiconductor module 1A. The collector wiring electrode 87c of the second semiconductor module 1B is electrically connected to the collector wiring electrode 87c of the first semiconductor module 1A.

The “package main body 80,” the “support electrode 84,” and the “plurality of wiring electrodes 87 (emitter wiring electrode 87e, gate wiring electrode 87g, and collector wiring electrode 87c)” according to the first semiconductor module 1A may be referred to as the “first package main body,” the “first electrode,” and the “plurality of first terminals (first emitter terminal, first gate terminal, and first collector terminal),” respectively.

The “package main body 80,” the “support electrode 84,” and the “plurality of wiring electrodes 87 (emitter wiring electrode 87e, gate wiring electrode 87g, and collector wiring electrode 87c)” according to the second semiconductor module 1B may be referred to as the “second package main body,” the “second electrode plate,” and the “plurality of second terminals (second emitter terminal, second gate terminal, and second collector terminal),” respectively.

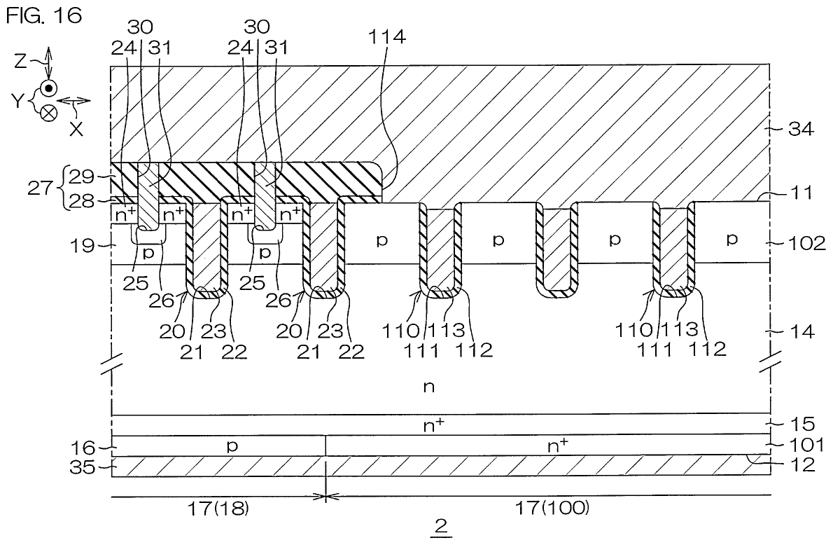

FIG. 16 is a cross-sectional view showing another configuration example of the IGBT device 2. In this embodiment, the IGBT device 2 consists of an RC-IGBT device (Reverse Conducting-IGBT device) that integrally includes an IGBT and a reflux diode (pn junction diode).

The IGBT device 2 includes one or a plurality of (preferably, a plurality of) the IGBT structures 18 provided in the first active region 17 and one or a plurality of (preferably, a plurality of) diode structures 100 provided in the first active region 17. For example, in a case in which a polygonal region including all of the IGBT structures 18 and all of the diode structures 100 in a plan view is set, the first active area SA1 of the first active region 17 is defined by the plane area of the polygonal region.

The plurality of IGBT structures 18 may be each formed in a quadrangular shape in a plan view. The plurality of diode structures 100 may be each formed in a quadrangular shape in a plan view. The plurality of IGBT structures 18 may be arrayed in a matrix manner or in a staggered manner at a distance from each other in the first and second directions X and Y in a plan view. The plurality of diode structures 100 may be arrayed at a distance from each other in the first and second directions X and Y so as to adjoin at least one IGBT structure 18. The plurality of diode structures 100 may be arrayed in the first direction X alternately with the plurality of IGBT structures 18.

Each of the IGBT structures 18 includes the base region 19, the plurality of first trench structures 20, the plurality of emitter regions 24, the plurality of contact holes 25, and the plurality of first contact regions 26. A description of these concrete configurations is as above, and hence is omitted.

Each of the diode structures 100 includes an n-type cathode region 101 formed in the surficial portion of the second main surface 12. The cathode region 101 is a region that has an n-type impurity concentration higher than the p-type impurity concentration of the collector region 16 and in which the conductivity type of a part of the collector region 16 has been changed from the p-type to the n-type.

Preferably, the cathode region 101 has an n-type impurity concentration higher than the semiconductor region 14 (buffer region 15). The cathode region 101 is formed in a layer shape extending along the second main surface 12, and is exposed from the second main surface 12. The cathode region 101 passes through the collector region 16 so as to be electrically connected to the semiconductor region 14 (buffer region 15).

Each of the diode structures 100 includes a p-type anode region 102 formed in the surficial portion of the first main surface 11. The anode region 102 may have a p-type impurity concentration substantially equal to that of the base region 19. Of course, the p-type impurity concentration of the anode region 102 may be higher than the p-type impurity concentration of the base region 19, or may be lower than the p-type impurity concentration of the base region 19.

The anode region 102 is formed in a layer shape extending along the first main surface 11 so as to face the cathode region 101 in the thickness direction of the first chip 10, and is exposed from the first main surface 11. The anode region 102 is shallower than the plurality of first trench structures 20. The anode region 102 may have a depth substantially equal to that of the base region 19.

Of course, the anode region 102 may be formed deeper than the base region 19. The anode region 102 makes a pn junction with the semiconductor region 14. Hence, a pn junction diode is formed in which the anode region 102 is set as an anode and in which the cathode region 101 is set as a cathode.

Each of the diode structures 100 includes a plurality of fourth trench structures 110 formed in the first main surface 11. A potential (in this embodiment, emitter potential Ve) differing from that of the first trench structure 20 (gate potential Vg) is given to the fourth trench structure 110. The fourth trench structure 110 may be referred to as an “emitter trench structure” or as an “anode trench structure.”

The plurality of fourth trench structures 110 are arrayed at a distance from each other in the first direction X, and are each formed in a belt shape extending in the second direction Y. The plurality of fourth trench structures 110 are formed in the first main surface 11 so as to pass through the anode region 102 and so as to reach the semiconductor region 14. Preferably, each of the fourth trench structures 110 has a depth substantially equal to that of each of the first trench structures 20.

The depth of each of the fourth trench structures 110 may be not less than 0.5 μm and not more than 10 μm. The depth of each of the fourth trench structures 110 may have a value that belongs to any one of the ranges of not less than 0.5 μm and not more than 2.5 μm, not less than 2.5 μm and not more than 5 μm, not less than 5 μm and not more than 7.5 μm, and not less than 7.5 μm and not more than 10 μm. Preferably, the depth of each of the fourth trench structures 110 is not less than 4 μm and not more than 8 μm.

Each of the fourth trench structures 110 includes a fourth trench 111, a fourth insulating film 112, and a fourth embedded electrode 113. The fourth trench 111 is formed in the first main surface 11, and defines a wall surface of the fourth trench structure 110. The fourth insulating film 112 covers a wall surface of the fourth trench 111 as a film. The fourth insulating film 112 may include a silicon oxide film. The fourth embedded electrode 113 is embedded in the fourth trench 111 with the fourth insulating film 112 between the fourth embedded electrode 113 and the fourth trench 111. In this embodiment, the fourth embedded electrode 113 includes conductive polysilicon.

The aforementioned first interlayer insulating film 27 includes a diode opening 114 that exposes each of the diode structures 100. The diode opening 114 exposes the anode region 102 and the plurality of fourth trench structures 110 in each of the diode structures 100. Preferably, the diode opening 114 exposes all of the fourth trench structures 110.

The aforementioned emitter electrode 34 is electrically connected to the plurality of emitter regions 24 and to the plurality of first contact regions 26 through the plurality of contact electrodes 31 on the first interlayer insulating film 27. The emitter electrode 34 enters the diode opening 114 from above the first interlayer insulating film 27.

The emitter electrode 34 is electrically connected to the anode region 102 and to the plurality of fourth trench structures 110 in the diode opening 114. The aforementioned collector electrode 35 makes an ohmic contact with the collector region 16 and the cathode region 101 that are exposed from the second main surface 12.

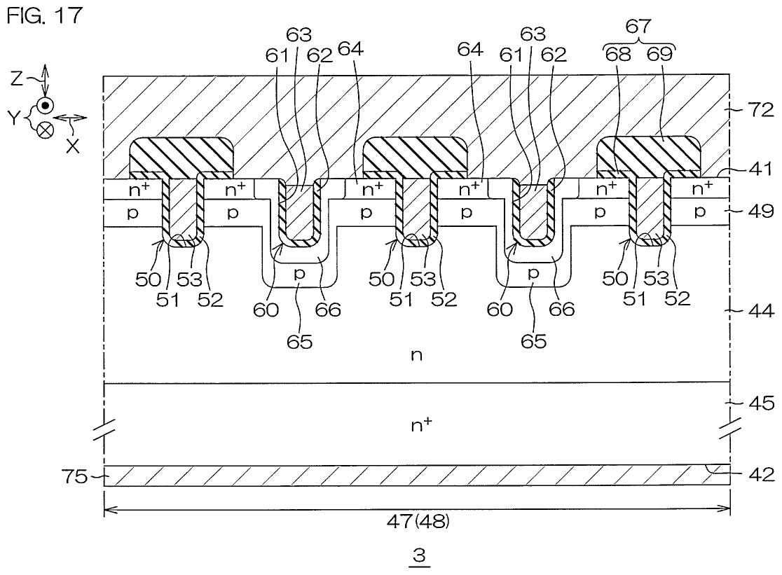

FIG. 17 is a cross-sectional view showing another configuration example of the MISFET device 3. Referring to FIG. 17, the MISFET device 3 may have the third trench structure 60 having a depth substantially equal to the second trench structure 50.

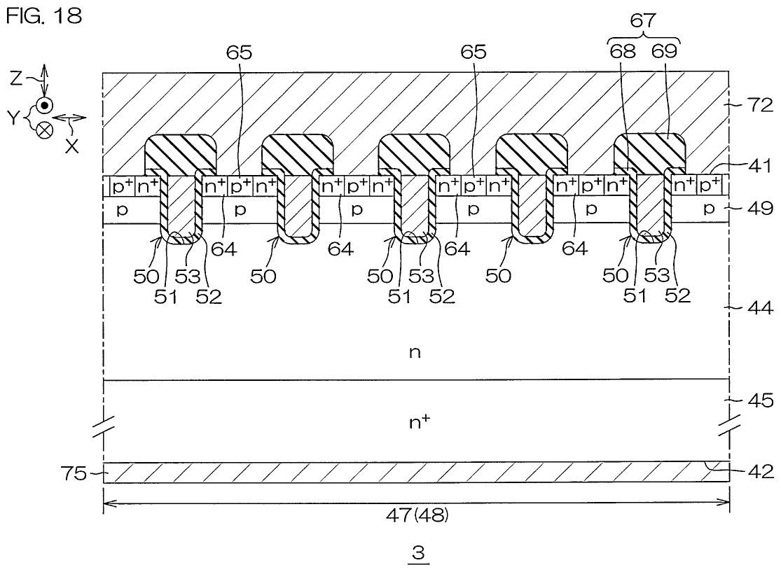

FIG. 18 is a cross-sectional view showing another configuration example of the MISFET device 3. Referring to FIG. 18, the MISFET device 3 is not necessarily required to include the third trench structure 60. In this case, the plurality of source regions 64 are formed in a region between two adjoining second trench structures 50 in the surficial portion of the body region 49. The aforementioned well region 65 is not formed.

The aforementioned plurality of second contact regions 66 are formed in a region between two adjoining second trench structures 50 in the surficial portion of the body region 49. The aforementioned source electrode 74 is electrically connected to the plurality of source regions 64 and to the plurality of second contact regions 66 through the second interlayer insulating film 67.

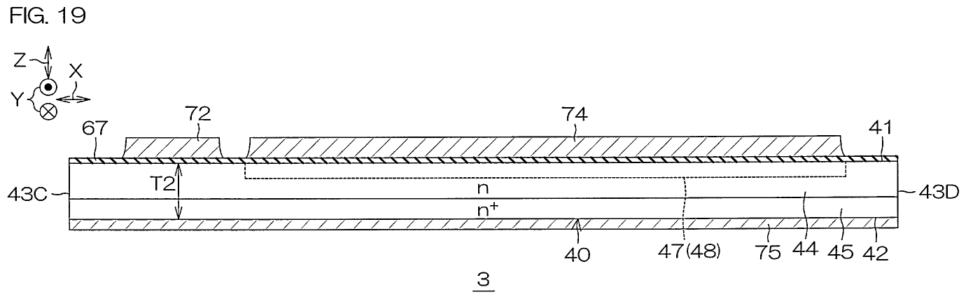

FIG. 19 is a cross-sectional view showing another configuration example of the MISFET device 3. Referring to FIG. 19, the MISFET device 3 may include the second semiconductor region 45 having a thickness smaller than the thickness of the first semiconductor region 44 inside the second chip 40. In other words, the second chip 40 may include a semiconductor substrate having a thickness smaller than the thickness of an epitaxial layer.

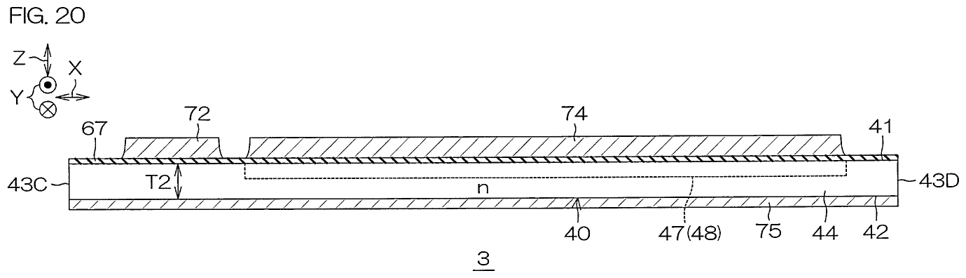

FIG. 20 is a cross-sectional view showing another configuration example of the MISFET device 3. Referring to FIG. 20, the MISFET device 3 does not have the second semiconductor region 45, and may include only the first semiconductor region 44 inside the second chip 40. In this case, the first semiconductor region 44 is exposed from the first main surface 41, the second main surface 42, and the first to fourth side surfaces 43A to 43D of the second chip 40. In other words, in this embodiment, the second chip 40 does not have a semiconductor substrate, and has a single-layer structure consisting of an epitaxial layer.

The aforementioned embodiment can be carried out in yet other forms. In the aforementioned embodiment, an example in which the first chip 10 is consisting of an Si chip was shown. However, the first chip 10 may be a wide bandgap semiconductor chip consisting of a monocrystal of the wide bandgap semiconductor chip. For example, the first chip 10 may be consisting of a SiC chip that is made of a SiC monocrystal.

In the aforementioned embodiment, an example in which the second chip 40 is consisting of a wide bandgap semiconductor chip was shown. However, the second chip 40 may be consisting of an Si chip that is made of an Si monocrystal.

In the aforementioned embodiment, the IGBT device 2 of a trench gate type that controls the inversion and non-inversion of a channel inside the first chip 10 was shown. However, the IGBT device 2 of a planar gate type that controls the inversion and non-inversion of a channel from above the first main surface 11 of the first chip 10 may be employed.

In the aforementioned embodiment, the MISFET device 3 of a trench gate type that controls the inversion and non-inversion of a channel inside the second chip 40 was shown. However, the MISFET device 3 of a planar gate type that controls the inversion and non-inversion of a channel from above the first main surface 41 of the second chip 40 may be employed.

In the aforementioned embodiments, a form in which the “first conductivity type” is an “n-type,” and the “second conductivity type” is a “p-type” was shown. However, in the aforementioned embodiments, a form may be employed in which the “first conductivity type” is a “p-type,” and the “second conductivity type” is an “n-type.” A concrete configuration in this case can be obtained by replacing the “n-type” with the “p-type” and, simultaneously, replacing the “p-type” with the “n-type” in the description given above and in the accompanying drawings.

Characteristic examples extracted from this description and from the drawings are hereinafter shown. Hereinafter, alphanumeric characters, etc., in parentheses represent corresponding components in the aforementioned embodiments, etc., and yet this representation does not denote that the scope of each clause is limited to the embodiments.

[A1] A semiconductor module (1) comprising: an IGBT device (2); and a MISFET device (3) that composes a parallel circuit together with the IGBT device (2), wherein a drain current (Ids) of the MISFET device (3) is to be generated in a voltage range less than a built-in voltage (Vbi) of the IGBT device (2), and a collector current (Ice) of the IGBT device (2) and a drain current (Ids) of the MISFET device (3) are to be generated in a voltage range equal to or more than the built-in voltage (Vbi).

[A2] The semiconductor module (1) according to A1, wherein the IGBT device (2) has a first breakdown voltage (VB1), and the MISFET device (3) has a second breakdown voltage (VB2) equal to or more than the first breakdown voltage (VB1).

[A3] The semiconductor module (1) according to A2, wherein the first breakdown voltage (VB1) is not less than 500 V and not more than 1500 V, and the second breakdown voltage (VB2) is not less than 500 V and not more than 3000 V.

[A4] The semiconductor module (1) according to any one of A1 to A3, wherein the IGBT device (2) includes a first chip (10) made of Si, and the MISFET device (3) includes a second chip (40) made of a wide bandgap semiconductor.

[A5] The semiconductor module (1) according to A4, wherein the wide bandgap semiconductor is SiC.

[A6] The semiconductor module (1) according to A4 or A5, wherein the first chip (10) has a first chip area (S1), and the second chip (40) has a second chip area (S2) smaller than the first chip area (S1).

[A7] The semiconductor module (1) according to A6, wherein the second chip area (S2) is not less than 0.1 times and not more than 0.6 times as large as the first chip area (S1).

[A8] The semiconductor module (1) according to any one of A4 to A7, wherein the second chip (40) is thinner than the first chip (10).

[A9] The semiconductor module (1) according to any one of A4 to A7, wherein the second chip (40) is thicker than the first chip (10).

[A10] The semiconductor module (1) according to any one of A1 to A9, wherein, with respect to a first characteristic (C1) showing an individual collector current (Ice) of the IGBT device (2) serving as a single independent device and with respect to a second characteristic (C2) showing an individual drain current (Ids) of the MISFET device (3) serving as a single independent device, when the individual drain current (Ids) at an intersection (P) between the first characteristic (C1) and the second characteristic (C2) is set as a first current value A and when the individual drain current (Ids) during application of the built-in voltage (Vbi) is set as a second current value B (B<A), a current ratio A/B of the first current value A to the second current value B is more than 1 and not more than 3 (1<A/B≤3).

[A11] The semiconductor module (1) according to A10, wherein an inclination of a straight line that connects the first current value A and the second current value B is more than 1 and not more than 30.

[A12] The semiconductor module (1) according to A10 or A11, wherein a difference value (A−B) between the first current value A and the second current value B is not less than 0.5 and not more than 30.

[A13] The semiconductor module (1) according to any one of A1 to A12, wherein the MISFET device (3) is a trench gate type, and the IGBT device (2) is a trench gate type.

[A14] The semiconductor module (1) according to any one of A1 to A13, wherein the IGBT device (2) is consisting of an RC-IGBT device that integrally includes an IGBT and a reflux diode.

[A15] The semiconductor module (1) according to any one of A1 to A14, further comprising: a support electrode (84); wherein the IGBT device (2) is arranged on the support electrode (84), and the MISFET device (3) is arranged on the support electrode (84) and electrically connected to the IGBT device (2) through the support electrode (84).

[A16] The semiconductor module (1) according to A15, further comprising: a wiring electrode (87) provided at a distance from the support electrode (84); a first conductive connection member (90A) electrically connected to the MISFET device (3) and to the wiring electrode (87); and a second conductive connection member (90C) electrically connected to the IGBT device (2) and to the wiring electrode (87).

[A17] The semiconductor module (1) according to A16, wherein the first conductive connection member (90A) is mechanically and electrically connected to the MISFET device (3) and to the wiring electrode (87), and the second conductive connection member (90C) is mechanically and electrically connected to the MISFET device (3) and to the IGBT device (2), and is electrically connected to the wiring electrode (87) through the first conductive connection member (90A).

Although the embodiments have been described in detail as above, these are merely concrete examples used to clarify the technical contents. Various technical ideas extracted from this description can be appropriately combined without being limited to the explanatory order, the order of the embodiments, or the like in the description.

What is claimed is:

1. A semiconductor module comprising:
an IGBT device; and
a MISFET device that composes a parallel circuit together with the IGBT device;
wherein a drain current of the MISFET device is to be generated in a voltage range less than a built-in voltage of the IGBT device, and a collector current of the IGBT device and a drain current of the MISFET device are to be generated in a voltage range equal to or more than the built-in voltage.

2. The semiconductor module according to claim 1,
wherein the IGBT device has a first breakdown voltage, and
the MISFET device has a second breakdown voltage equal to or more than the first breakdown voltage.

3. The semiconductor module according to claim 2,
wherein the first breakdown voltage is not less than 500 V and not more than 1500 V, and
the second breakdown voltage is not less than 500 V and not more than 3000 V.

4. The semiconductor module according to claim 1,
wherein the IGBT device includes a first chip made of Si, and
the MISFET device includes a second chip made of a wide bandgap semiconductor.

5. The semiconductor module according to claim 4,
wherein the wide bandgap semiconductor is SiC.

6. The semiconductor module according to claim 4,
wherein the first chip has a first chip area, and
the second chip has a second chip area smaller than the first chip area.

7. The semiconductor module according to claim 6,
wherein the second chip area is not less than 0.1 times and not more than 0.6 times as large as the first chip area.

8. The semiconductor module according to claim 4,
wherein the second chip is thinner than the first chip.

9. The semiconductor module according to claim 4,
wherein the second chip is thicker than the first chip.

10. The semiconductor module according to claim 1,
wherein, with respect to a first characteristic showing an individual collector current of the IGBT device serving as a single independent device and with respect to a second characteristic showing an individual drain current of the MISFET device serving as a single independent device,
when the individual drain current at an intersection between the first characteristic and the second characteristic is set as a first current value A and when the individual drain current during application of the built-in voltage is set as a second current value B (B<A),
a current ratio A/B of the first current value A to the second current value B is more than 1 and not more than 3 (1<A/B≤3).

11. The semiconductor module according to claim 10,
wherein an inclination of a straight line that connects the first current value A and the second current value B is more than 1 and not more than 30.

12. The semiconductor module according to claim 10,
wherein a difference value (A−B) between the first current value A and the second current value B is not less than 0.5 and not more than 30.

13. The semiconductor module according to claim 1,
wherein the MISFET device is a trench gate type, and
the IGBT device is a trench gate type.

14. The semiconductor module according to claim 1,
wherein the IGBT device is consisting of an RC-IGBT device that integrally includes an IGBT and a reflux diode.

15. The semiconductor module according to claim 1, further comprising:
a support electrode;
wherein the IGBT device is arranged on the support electrode, and
the MISFET device is arranged on the support electrode and electrically connected to the IGBT device through the support electrode.

16. The semiconductor module according to claim 15, further comprising:
a wiring electrode provided at a distance from the support electrode;
a first conductive connection member electrically connected to the MISFET device and to the wiring electrode; and
a second conductive connection member electrically connected to the IGBT device and to the wiring electrode.

17. The semiconductor module according to claim 16,
wherein the first conductive connection member is mechanically and electrically connected to the MISFET device and to the wiring electrode, and
the second conductive connection member is mechanically and electrically connected to the MISFET device and to the IGBT device, and is electrically connected to the wiring electrode through the first conductive connection member.
